(19) United States
(12) Patent Application Publication
(10) Pub. No.: US 2025/0207295 A1
(43) Pub. Date: Jun. 26, 2025

(54) SEED CRYSTAL HOLDERS AND CRYSTAL GROWTH METHODS

(71) Applicant: MEISHAN BOYA ADVANCED MATERIALS CO., LTD., Meishan (CN)

(72) Inventors: Yu WANG, Meishan (CN); Weiming GUAN, Meishan (CN); Peng GU, Meishan (CN); Pei LEI, Meishan (CN)

(73) Assignee: MEISHAN BOYA ADVANCED MATERIALS CO., LTD., Meishan (CN)

(21) Appl. No.: 19/074,419

(22) Filed: Mar. 9, 2025

Related U.S. Application Data
(63) Continuation of application No. PCT/CN2023/117096, filed on Sep. 5, 2023.

(30) Foreign Application Priority Data
Sep. 9, 2022 (CN) 202222415184.0

(51) Int. Cl. C30B 15/32; C30B 35/00

(52) U.S. Cl. CPC C30B 15/32; C30B 35/007

(57) ABSTRACT

Embodiments of the present disclosure provide a seed crystal holder and a crystal growth method. The seed crystal holder includes a seed crystal holder body and a connecting rod. The seed crystal holder body is fixed to one end of the connecting rod, and a seed crystal is provided on one side of the seed crystal holder body away from the connecting rod.

### CROSS-REFERENCE TO RELATED APPLICATIONS

This application is a Continuation of International Application No. PCT/CN2023/117096, filed on Sep. 5, 2023, which claims priority to Chinese Application No. 202222415184.0, filed Sep. 9, 2022, the entire contents of which are hereby incorporated by reference.

### TECHNICAL FIELD

The present disclosure relates to the field of crystal preparation, and in particular, to seed crystal holders and crystal growth methods.

### BACKGROUND

The liquid-phase growth technique is one of the methods used to grow crystals (e.g., silicon carbide single crystals). In crystal (e.g., semiconductor crystal) growth using the liquid-phase growth technique, it is necessary to bond seed crystals to seed crystal holders before crystal growth, and the quality of bonding the seed crystals directly affects the quality of synthesized crystals. When preparing the crystals using the Czochralski manner, the seed crystals are bonded to the seed crystal holders, the seed crystals contact with the molten liquid by lowering the seed crystal holders, thereby initiating crystallization for crystal growth. Therefore, the structural design of the seed crystal holders, the bonding of the seed crystal holders with the crystals, etc., are essential for crystal growth.

### SUMMARY

One or more embodiments of the present disclosure provide a seed crystal holder including a seed crystal holder body and a connecting rod. The seed crystal holder body may be fixed to one end of the connecting rod, and a seed crystal bonding surface may be provided on one side of the seed crystal holder body away from the connecting rod.

In some embodiments, the seed crystal holder body may include a first inner cavity, and the first inner cavity may be hollow. The connecting rod may be provided with a passageway for circulating a cooling medium, and the passageway may be connected to the first inner cavity.

In some embodiments, the seed crystal holder body may be provided with a first through hole that is connected to the first inner cavity.

In some embodiments, the inner cavity may be provided with a cooling medium diffusion structure.

In some embodiments, the cooling medium diffusion structure may include a housing. A second inner cavity may be formed in the housing, the housing may be provided with a plurality of diffusion holes, the passageway may be connected to the second inner cavity, and the plurality of diffusion holes may connect the first inner cavity and the second inner cavity.

In some embodiments, the seed crystal holder may further include a cooling apparatus. The cooling apparatus may be configured to deliver the cooling medium to the passageway, and the cooling medium may be configured to flow within the passageway at a preset flow rate.

In some embodiments, the cooling medium may be an inert gas with a preset flow rate of more than 0.4 m/s.

In some embodiments, the seed crystal holder may further include a weight-enhancing structure, and the weight-enhancing structure may be connected to the seed crystal holder body.

In some embodiments, the seed crystal holder may further include a cooling structure provided on the connecting rod, and the cooling structure may be configured to cool the cooling medium within the passageway.

In some embodiments, the seed crystal holder may further include a driving mechanism and a stirring mechanism. The other end of the connecting rod may be connected to the driving mechanism, and the driving mechanism may be configured to drive, via the connecting rod, the seed crystal holder body to rotate around an axis of the connecting rod. The stirring mechanism may be connected to the seed crystal holder body, and the stirring mechanism may be configured to stir molten liquid for crystal growth.

In some embodiments, the stirring mechanism may include a mounting rod and a stirring paddle, and the stirring paddle may be located on a side of the seed crystal bonding surface away from the connecting rod.

In some embodiments, the seed crystal holder may include a plurality of stirring mechanisms, and the plurality of the stirring mechanisms may be disposed around the seed crystal holder body.

In some embodiments, a material of the stirring mechanism may be tungsten alloy and/or high temperature ceramic.

In some embodiments, the seed crystal holder body may include at least two subsections, and a half-groove may be provided on each subsection among the at least two subsections. The seed crystal holder may further include a locking structure and a snapping structure, and the snapping structure may be provided at an end of the connecting rod that is connected to the seed crystal holder body. The at least two subsections may be spliced such that the half-groove on each subsection among the at least two subsections may be spliced to form a snapping groove, and the snapping structure may snap into the snapping groove. The locking structure may fix the at least two subsections that are spliced.

In some embodiments, the at least two sub-sections may include a first subsection and a second subsection, structures of the first subsection and the second subsection may be the same, and the first subsection and the second subsection may be disposed symmetrically with an axis of the connecting rod.

In some embodiments, the snapping groove may include a first groove body and a second groove body arranged in a direction of an axis of the connecting rod, and the first groove body may be closer to the seed crystal bonding surface than the second groove body. An area of the first groove body along a cross-section perpendicular to the axis of the connecting rod may be greater than an area of the second groove body along the cross-section perpendicular to the axis of the connecting rod. An area of the snapping structure along the cross-section perpendicular to the axis of the connecting rod may be greater than an area of the connecting rod along the cross-section perpendicular to the axis of the connecting rod.

In some embodiments, the snapping structure may be a polyhedron.

In some embodiments, the locking structure may include an annular groove and a locking ring. The annular groove may be provided around an outer wall of the seed crystal holder body, the locking ring may be provided outside the at least two subsections after splicing, and the locking ring may be provided within the annular groove.

In some embodiments, the seed crystal holder may further include a protective bracket, and the protective bracket may be annular. The protective bracket may be provided with a holding cavity matched with a shape of the seed crystal holder body, the protective bracket may be provided around the seed crystal holder body, and the protective bracket may be provided around an end of the connecting rod that is connected to the seed crystal holder body.

In some embodiments, the seed crystal holder may further include a first protective sleeve, and the first protective sleeve may be annular. The first protective sleeve may be provided outside the connecting rod, and the first protective sleeve may be provided between the connecting rod and the protective bracket.

In some embodiments, the connecting rod may include first outer diameter section and a second outer diameter section along an axial direction of the connecting rod. An outer diameter of the first outer diameter section may be less than an outer diameter of the second outer diameter section, and the first outer diameter section may be closer to the seed crystal holder body than the second outer diameter section. The first protective sleeve may include a first inner diameter section and a second inner diameter section along the axial direction of the connecting rod. An outer diameter of the first inner diameter section may be less than an inner diameter of the second inner diameter section, the first inner diameter section may match the first outer diameter section, and the second inner diameter section may match the first inner diameter section.

In some embodiments, a side surface of the protective bracket away from the connecting rod may be provided with a second protective sleeve. The second protective sleeve may be annular, the second protective sleeve may be embedded in the protective bracket, and the second protective sleeve may surround the holding cavity.

In some embodiments, an end of the second protective sleeve away from the connecting rod may be affixed to the seed crystal when there is a seed crystal bonded on the seed crystal bonding surface.

In some embodiments, a first groove may be provided on the side surface of the protective bracket away from the connecting rod. A diameter of the first groove may be greater than a diameter of an opening of a side of the holding cavity depart from the connecting rod. The first groove may include a connecting portion connected to the opening and an annular portion encircling the connecting portion. A bottom surface of the annular portion may be located in a same plane as the seed crystal bonding surface. The annular protective sleeve may be provided on the bottom surface of the annular portion.

In some embodiments, the diameter of the first groove may be 5 mm-10 mm greater than a diameter of the opening.

In some embodiments, the seed crystal bonding surface may be bonded with a graphite paper, and the graphite paper may protrude in a direction away from the connecting rod from a side surface of the second protective sleeve away from the connecting rod.

One or more embodiments of the present disclosure provide a seed crystal bonding device including one or more bonding assemblies. The bonding assemblies may include a support member and a pressure applying member. The support member may support a seed crystal holder, and the pressure applying member may apply a pressure. The pressure may biaxially press the seed crystal holder and the seed crystal on the seed crystal holder.

In some embodiments, the support member may include a first pressure member and a second pressure member, and the pressure applying member may include a first pressure plate. A sidewall of the first pressure plate may include at least one first air venting hole. The second pressure member may be nested to the first pressure plate. During a bonding and fixation process of a seed crystal, the seed crystal may be placed on an upper surface of the second pressure member and the seed crystal holder may be placed on the upper surface of the seed crystal, and the first pressure plate may apply pressure on the seed crystal holder.

In some embodiments, a bottom of the first pressure member may include a second through hole, a bottom of the second pressure member may include a first hump, and the first hump may cooperate with the second through hole to realize a nested connection of the first pressure member and the second pressure member.

In some embodiments, a cross-sectional diameter of a first air venting hole of the at least one first air venting hole may be within a range of 0.01 mm-10 mm.

In some embodiments, after the second pressure member is nested to the first pressure plate, a vertical distance between the at least one first air venting hole and the upper surface of the second pressure member may be within a range of 0.2 mm-5 mm.

In some embodiments, a sidewall of the second pressure member may include at least one second air venting hole, and the at least one first air venting hole may correspond to at least portion of the at least one second air venting hole.

In some embodiments, a cross-sectional diameter of a second air venting hole of the at least one second air venting hole may be within a range of 0.01 mm-10 mm.

In some embodiments, a vertical distance between the at least one second air venting hole and the upper surface of the second pressure member may be within a range of 0.2 mm-5 mm.

In some embodiments, a height of the second pressure member may be less than a height of the first pressure member.

In some embodiments, the seed crystal holder may be threadedly connected to the first pressure member.

In some embodiments, a bottom of the first pressure plate may include a second hump and an upper portion of the seed crystal holder may include a second groove, and the second hump may cooperate with the second groove to realize a connection between the first pressure plate and the seed crystal holder.

In some embodiments, the seed crystal holder may be provided on the annular base, and the cover body may include an annular sidewall and a cover plate. The annular sidewall may be socketed outside the annular base, and the cover body may apply pressure on the seed crystal on the seed crystal holder.

In some embodiments, the seed crystal bonding device may further include a first connecting member and a second connecting member. The first connecting member may be provided on the annular base, and the second connecting member may be provided on the cover body. The first connecting member may be detachably connected with the second connecting member. When the first connecting member is connected with the second connecting member, the cover plate of the cover body may apply pressure on the seed crystal on the seed crystal holder.

In some embodiments, the annular base may be provided with a locking structure, and the locking structure may fix the seed crystal holder to the annular base.

In some embodiments, a connection threaded hole may be provided on a side of the seed crystal holder away from a seed crystal bonding surface. The locking structure may include a locking disk, a locking member, and a locking nut. The locking member may include a tray, a first threaded rod, and a second threaded rod. The tray supports the side of the seed crystal holder away from the seed crystal bonding surface. The first threaded rod may cooperate with the connection threaded hole. The locking disk may be provided with a mounting hole. The second threaded rod may pass through the mounting hole. The locking nut may cooperate with the second threaded rod. The locking nut and the tray may be provided on two sides of the locking disk along an axial direction of the mounting hole.

In some embodiments, the tray may be made of an elastic material.

In some embodiments, an inner wall of the annular base may be provided with a support structure, and the support structure may include an annular connecting plate, an annular support plate, and an annular support hump. An outer ring of the annular support plate may connect the annular connecting plate, an inner ring of the annular support plate may be provided with the annular support hump, the annular support hump may support the seed crystal support, and the annular connecting plate may connect the inner wall of the annular base.

In some embodiments, the cover body may be provided with an air bubble removing apparatus, and the air bubble removing apparatus may be configured to remove air bubbles between the seed crystal and the seed crystal holder.

In some embodiments, the air bubble removing apparatus may include an insert groove, an insert plate, and a roller. The insert groove may be provided on the cover body, the insert plate may be provided in the insert groove, and the roller may be provided at one end of the insert plate. The insert plate may be configured to move within the insert groove to drive the roller to roll the seed crystal.

In some embodiments, a pull ring may be provided at another end of the insert plate.

In some embodiments, the seed crystal bonding device may further include a plurality of the bonding assemblies. The support member may include a support disk, the support disk may be configured to support the seed crystal and the seed crystal holder, and the seed crystal may be located between the seed crystal and the seed crystal holder. The seed crystal bonding device may further include a support frame and a plurality of pressure applying driving members provided on the support frame. The support disk may be provided on the support frame, the seed crystal bonding device may include the plurality of bonding assemblies, and the plurality of pressure applying driving members may be connected with a plurality of pressure applying members. The plurality of pressure applying driving members may cause the plurality of pressure applying members to apply pressure on the seed crystal holder toward the support disk

In some embodiments, the support frame may include a plurality of support rods extending along a vertical direction. The plurality of the support rods may be arranged at intervals along a circumferential direction of the support disk. The plurality of the pressure applying driving members may be provided on at least one support rod of the plurality of the support rods. The plurality of the pressure applying driving members may be spaced apart along the vertical direction, and a plurality of seed crystal bonding assemblies may be spaced apart along the vertical direction.

In some embodiments, the plurality of the pressure applying driving members may include a pneumatic pressure applying driving member or a hydraulic pressure applying driving member.

In some embodiments, at least one support rod provided with the plurality of the pressure applying driving members may be provided with a pressure-transferring medium passage, and at least one pressure applying driving member may be connected with the pressure-transferring medium passage through a valve.

In some embodiments, the support disk may be rotatably disposed on the support frame, a rotation axis of the support disk may be parallel to a support rod, and the seed crystal bonding device may further include a rotary driving member connected with the support disk to drive the support disk to rotate.

In some embodiments, the rotary driving member may include a magnetic element, a power source, and a magnetic driving member. The magnetic driving member may be magnetically coupled to the magnetic element. The magnetic element may be fixed on the support disk. The magnetic driving member may be fixed on an output end of the power source. The power source may drive the magnetic driving member to rotate to drive the magnetic element to drive the support disk to rotate.

In some embodiments, the plurality of pressure applying members may include limiting pressure plates provided on the plurality of support rods, the plurality of the pressure applying driving members may include a first sub-driving member and a second sub-driving member, and the first sub-driving member and the second sub-driving member may be provided on different support rods of the plurality of support rods. The first sub-driving member and the second sub-driving member may be spaced apart along a circumferential direction of the limiting pressure plates, and the first sub-driving member and the second sub-driving member may be both connected with the limiting pressure plates.

In some embodiments, the seed crystal bonding device may further include a pressure sensor configured to determine a pressure applied by each of the plurality of pressure applying members.

In some embodiments, the seed crystal bonding device may further include a controller, and the controller may be in signal communication with both the valve and the pressure sensor. The controller may be configured to adjust an opening of the valve based on pressure data sensed by the pressure sensor.

One or more embodiments of the present disclosure provide a crucible including a crucible body, a driving assembly, and a temperature field holding disk. The driving assembly may include a driving source and a connecting mechanism. The connecting structure may be connected between the driving source and a bottom of the crucible body. The driving assembly may drive the crucible body to rotate about an axis of the crucible body relative to the temperature field holding disk. The temperature field holding disk may be provided on the connecting mechanism and may be located between the driving source and the bottom of the crucible body.

In some embodiments, the connecting mechanism may include a rotating column and a first bearing disk, the first bearing disk may be provided at one end of the rotating column, and the driving source may be connected to another end of the rotating column.

In some embodiments, the first bearing disk may include a plurality of stepped grooves arranged concentrically.

In some embodiments, the connecting mechanism may include a second bearing disk. The second bearing disk may be in the shape of a ring. The second bearing disk may be provided between the first bearing disk and the driving source. An inner ring of the second bearing disk may be fixed to an outer wall of the rotating column. The second bearing disk may be connected to the temperature field holding disk by a ball structure.

In some embodiments, a material of the temperature field holding disk may include at least one of mullite, corundum, or alumina.

In some embodiments, the crucible may further include a plurality of telescopic support rods, and one end of each the plurality of telescopic support rods may be connected to a bottom of the temperature field holding disk.

In some embodiments, the crucible may further include a connecting ring and a locking mechanism. A sidewall of the connecting ring may be provided with a locking hole. The connecting ring may be socketed on an output shaft of the driving source and another end of the rotating column. The locking hole may cooperate with the locking mechanism to fix the connecting ring, the output shaft of the driving source, and the rotating column.

One or more embodiments of the present disclosure provide a crystal growth method. The crystal growth method may be implemented with a seed crystal holder as described in the preceding embodiments. The crystal growth method may include: bonding seed crystals to a seed crystal bonding a seed crystal to a seed crystal bonding surface of a seed crystal holder body; sinking the seed crystal holder with the seed crystal into a melt for crystal growth in a crucible, and a side surface of the seed crystal away from the seed crystal holder is located at a position with a highest temperature of the melt; growing the crystal using a Czochralski manner.

In some embodiments, a portion of the seed crystal holder body may be provided in the melt and another portion of the seed crystal holder body is provided outside the melt.

In some embodiments, the seed crystal holder may be capable of rotating about an axis of a connecting rod, and the crucible may be capable of rotating about an axis of the crucible. The axis of the connecting rod may be parallel to the axis of the crucible. The process of growing the crystal using a Czochralski manner may include controlling the seed crystal holder and the crucible to rotate in opposite directions.

In some embodiments, a rotational speed of the seed crystal holder may be within a range of 0 rpm-20 rpm. A rotational speed of the crucible may be within a range of 0 rpm-20 rpm.

In some embodiments, a product of a numerical value of the rotational speed of the seed crystal holder and a numerical value of the rotational speed of the crucible may be 20 or 150.

In some embodiments, before sinking the seed crystal holder with the seed crystal into the melt for crystal growth, the crystal growth method may further include heating the melt to be within a range of 1720° C.-1780° C.

In some embodiments, the process of growing the crystal using a Czochralski manner may include keeping the seed crystal holder with the seed crystal to be immersed in the melt for 10-30 minutes; and lifting the seed crystal holder at a lifting speed within a range of 0.01 mm/h-0.2 mm/h for crystal growth.

In some embodiments, the process of growing the crystal using a Czochralski manner may include lifting, after 10-30 hours of crystal growth, the crystal away from the melt at a lifting speed within a range of 30 mm/h-40 mm/h. A spacing height between the crystal and a surface of the melt is within a range of 15 mm-25 mm.

In some embodiments, the bonding a seed crystal to a seed crystal bonding surface of a seed crystal holder body may include making a diameter of the seed crystal 5 mm-10 mm greater than a diameter of the seed crystal holder body and the seed crystal protrude 0.1 mm-0.2 mm from a side surface of a protective bracket away from the connecting rod.

In some embodiments, a side surface of a protective bracket away from the connecting rod may be provided with an annular second protective sleeve, and the second protective sleeve may be embedded in the protective bracket and the annular second protective sleeve is provided around a holding cavity. The process of bonding a seed crystal to a seed crystal bonding surface of a seed crystal holder body may include affixing the seed crystal to an end of the annular second protective sleeve away from the connecting rod and bonding the seed crystal to a seed crystal bonding surface of the seed crystal holder body. The crystal growth method may further include cutting the seed crystal holder along a cutting plane parallel to the seed crystal bonding surface to separate the seed crystal holder from the crystal after crystal growth is complete. The cutting plane may cover the seed crystal holder body, the protective bracket, and the annular second protective sleeve.

### BRIEF DESCRIPTION OF THE DRAWINGS

The present disclosure is further illustrated in terms of exemplary embodiments. These exemplary embodiments are described in detail with reference to the drawings. These embodiments are non-limiting exemplary embodiments, in which like reference numerals represent similar structures, and wherein:

FIG. 1 is a diagram illustrating an exemplary seed crystal holder according to some embodiments of the present disclosure;

FIG. 2A is an exemplary cross-sectional view of another seed crystal holder according to some embodiments of the present disclosure;

FIG. 2B is an exemplary cross-sectional view of another seed crystal holder according to some embodiments of the present disclosure;

FIG. 2C is an exemplary cross-sectional view of another seed crystal holder according to some embodiments of the present disclosure;

FIG. 3 is an exemplary cross-sectional view of another seed crystal holder according to some embodiments of the present disclosure;

FIG. 4 is an exemplary cross-sectional view of another seed crystal holder according to some embodiments of the present disclosure;

FIG. 5 is an exemplary cross-sectional view of another seed crystal holder according to some embodiments of the present disclosure;

FIG. 6A is a diagram illustrating an exemplary front view of a first subsection according to some embodiments of the present disclosure;

FIG. 6B is a diagram illustrating an exemplary front view of a second subsection according to some embodiments of the present disclosure;

FIG. 6C is a diagram illustrating an exemplary front view of a first subsection splicing with the second subsection according to some embodiments of the present disclosure;

FIG. 7 is a diagram illustrating an exemplary top view of another seed crystal holder according to some embodiments of the present disclosure;

FIG. 8 is an exemplary cross-sectional view of a locking structure according to some embodiments of the present disclosure;

FIG. 9 is an exemplary bottom view of a locking structure according to some embodiments of the present disclosure;

FIG. 10 is an exemplary cross-sectional view of another seed crystal holder according to some embodiments of the present disclosure;

FIG. 11 is a diagram illustrating exemplary modules of a seed crystal bonding device according to some embodiments of the present disclosure;

FIG. 12 is a diagram illustrating an exemplary seed crystal bonding device according to some embodiments of the present disclosure;

FIG. 13 is a diagram illustrating an exemplary seed crystal assembly according to some embodiments of the present disclosure;

FIG. 14 is an exemplary cross-sectional view of another seed crystal bonding device according to some embodiments of the present disclosure;

FIG. 15A is a diagram illustrating an exemplary locking member according to some embodiments of the present disclosure;

FIG. 15B is an exemplary top view of an air bubble removing apparatus according to some embodiments of the present disclosure;

FIG. 16 is a diagram illustrating another exemplary seed crystal bonding device according to some embodiments of the present disclosure;

FIG. 17 is a diagram illustrating exemplary modules of a crucible according to some embodiments of the present disclosure;

FIG. 18 is a diagram illustrating an exemplary connecting mechanism according to some embodiments of the present disclosure;

FIG. 19 is a diagram illustrating an exemplary second bearing disk according to some embodiments of the present disclosure;

FIG. 20A is a diagram illustrating an exemplary telescopic support rod according to some embodiments of the present disclosure;

FIG. 20B is a diagram illustrating an exemplary temperature field holding disk according to some embodiments of the present disclosure;

FIG. 21 is a diagram illustrating an exemplary connecting ring according to some embodiments of the present disclosure;

FIG. 22 is a flowchart illustrating an exemplary crystal growth method according to some embodiments of the present disclosure; and

FIG. 23 is a schematic diagram illustrating a generated crystal according to some embodiments of the present disclosure.

### DETAILED DESCRIPTION

To more clearly illustrate the technical solutions related to the embodiments of the present disclosure, a brief introduction of the drawings referred to the description of the embodiments is provided below. Obviously, the drawings described below are only some examples or embodiments of the present disclosure. Those having ordinary skills in the art, without further creative efforts, may apply the present disclosure to other similar scenarios according to these drawings. Unless obviously obtained from the context or the context illustrates otherwise, the same numeral in the drawings refers to the same structure or operation.

It should be understood that “system,” “device,” “unit,” and/or “module” as used herein is a manner used to distinguish different components, elements, parts, sections, or assemblies at different levels. However, if other words serve the same purpose, the words may be replaced by other expressions.

As shown in the present disclosure and claims, the words “one,” “a,” “a kind,” and/or “the” are not especially singular but may include the plural unless the context expressly suggests otherwise. In general, the terms “comprise,” “comprises,” “comprising,” “include,” “includes,” and/or “including”, merely prompt to include operations and elements that have been clearly identified, and these operations and elements do not constitute an exclusive listing. The methods or devices may also include other operations or elements.

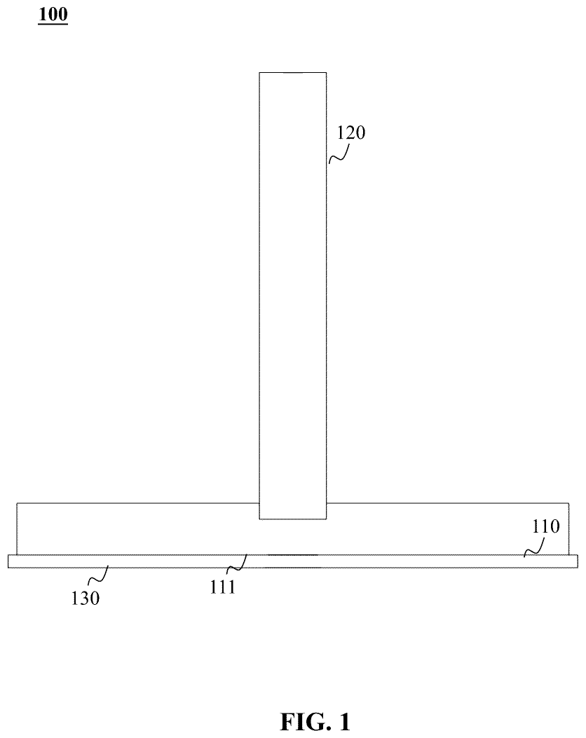

FIG. 1 is a diagram illustrating an exemplary seed crystal holder according to some embodiments of the present disclosure.

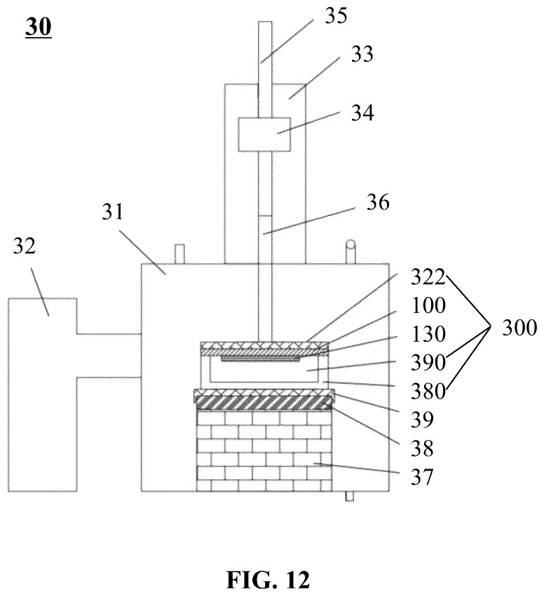

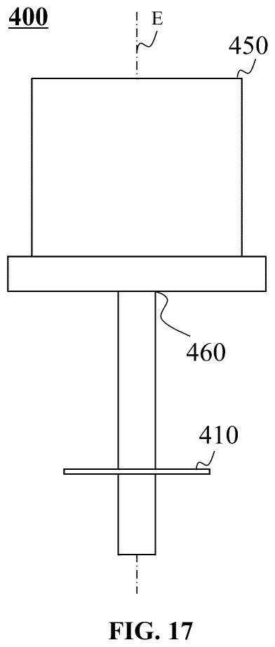

The present disclosure provides a seed crystal holder 100 configured for crystal growth. When preparing crystals, a seed crystal 130 needs to be bonded to the seed crystal holder 100, the seed crystal holder 100 may be provided on a seed crystal bonding device 30, and a raw material for preparing crystals may be placed inside a crucible 400. By heating a temperature field in which the seed crystal holder 100 and the crucible 400 are located, the raw material is volatilized into a gas-phase component and moves up to the seed crystal 130, to realize the crystal growth of the liquid-phase growth technique. The seed crystal 130 may include a semiconductor seed crystal, for example, a silicon carbide seed crystal. More descriptions regarding the seed crystal bonding device 30 may be found in FIGS. 12-16 and related descriptions thereof. More descriptions regarding the crucible 400 may be found in FIGS. 17-20B and related descriptions thereof.

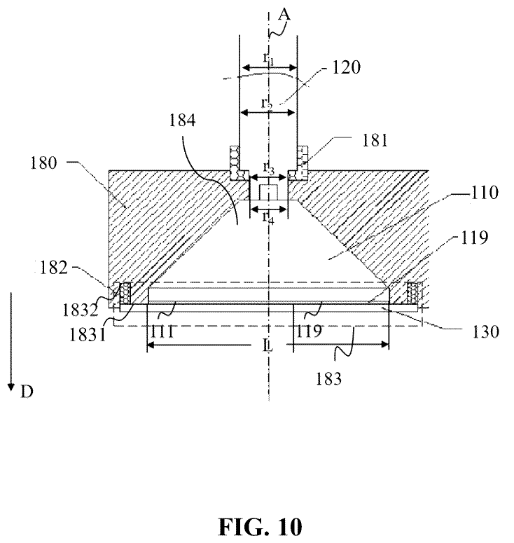

As shown in FIG. 1, the seed crystal holder 100 may include a seed crystal holder body 110 and a connecting rod 120. The seed crystal holder body 110 is configured to fix the seed crystal 130, and the material of the seed crystal holder body 110 may be graphite. The seed crystal holder body 110 may be bonded to the seed crystal 130 under certain conditions (e.g., vacuuming, heating, etc.). The seed crystal holder body 110 may be provided in a columnar shape (such as the seed crystal holder body 110 in a cylindrical shape shown in FIG. 1), a truncated cone shape (such as the seed crystal holder body 110 in a truncated cone shape shown in FIG. 10), or other feasible shapes.

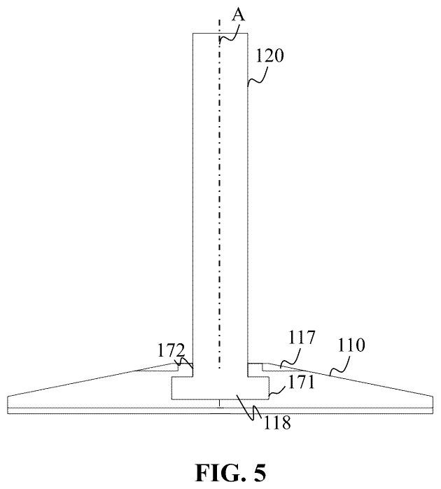

The connecting rod 120 is configured to connect the seed crystal holder body 110 with a driving device (a driving mechanism 150 below), such that the driving device may drive the seed crystal holder body 110 in axial movement along the connecting rod 120 or rotate around an axis of the connecting rod 120. As shown in FIG. 1, the seed crystal holder body 110 is fixed to one end of the connecting rod 120. There may be various ways of connecting the seed crystal holder body 110 to the connecting rod 120. In some embodiments, a connection threaded hole is provided on a side of the seed crystal holder body 110 away from a seed crystal bonding surface 111, and the connecting rod 120 may be provided with a connection thread. The connecting rod 120 may be connected with the seed crystal holder body 110 through a combination of the connection thread and the connection threaded hole. The connecting rod 120 may also be connected to the seed crystal holder body 110 in other feasible connection manners. The other feasible connection manners may be described in FIGS. 5-7 and their related descriptions.

In some embodiments, as shown in FIG. 1, the seed crystal bonding surface 111 is provided on a side of the seed crystal holder body 110 away from the connecting rod for bonding the seed crystal 130 to the seed crystal holder body 110. The seed crystal bonding surface 111 may be planar to ensure that the seed crystal 130 may be stably bonded to the seed crystal holder body 110. The seed crystal bonding surface 111 may be disposed on an end face of the seed crystal holder body 110. For example, when the seed crystal holder body 110 is a cylinder, the seed crystal bonding surface 111 may be at an end face of the cylinder. As another example, when the seed crystal holder body 110 is a truncated cone, the seed crystal bonding surface 111 may be at an end face with a larger area in the truncated cone.

In some embodiments of the present disclosure, by fixing the seed crystal holder body 110 in the seed crystal holder 100 to one end of the connecting rod 120, it is possible to cause the connecting rod 120 to exert a pressure on the seed crystal holder body, and the seed crystal 130 may be stably bonded to the seed crystal bonding surface 111, which helps to improve the quality of crystal growth.

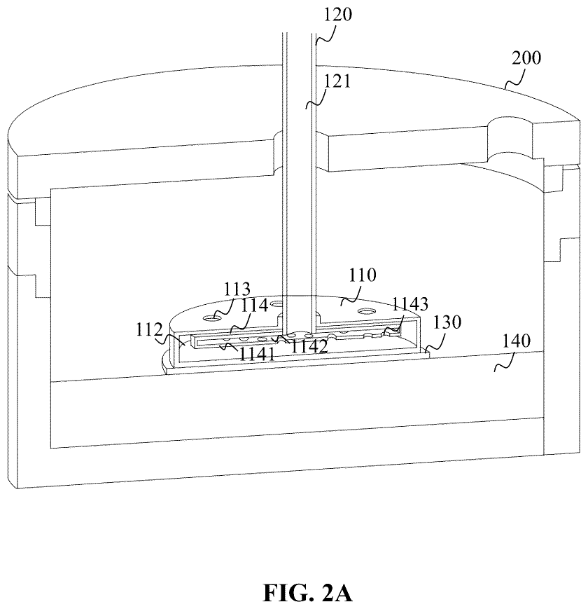

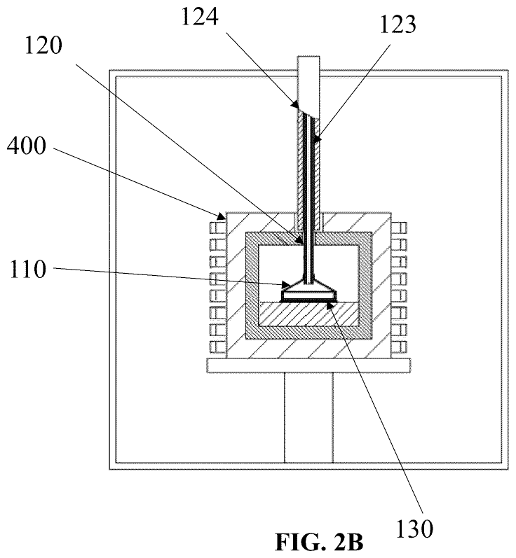

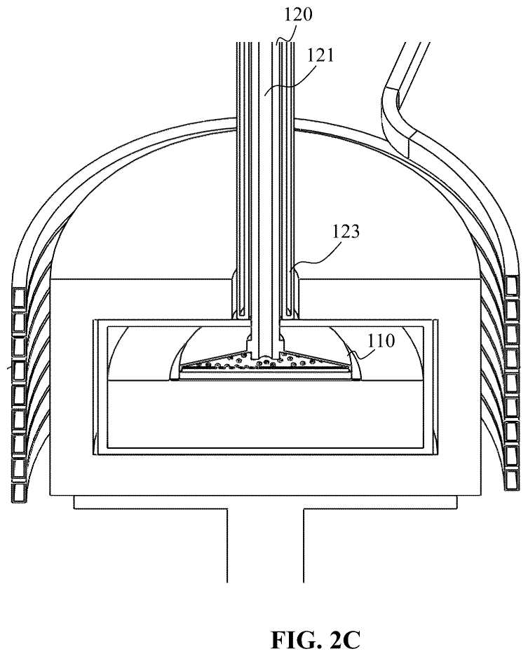

In some embodiments, as shown in FIG. 2A, the seed crystal holder body 110 may further include a first inner cavity 112, and the first inner cavity 112 is hollow. The connecting rod 120 is provided with a passageway 121 for circulating a cooling medium, and the passageway 121 is connected to the first inner cavity 112. The first inner cavity 112 is an internal space formed by a hollow structure of the seed crystal holder body 110 for collecting the cooling medium to reduce a temperature of the seed crystal holder body 110. In some embodiments, a shape of the first inner cavity 112 matches a shape of the seed crystal holder body 110 to allow for a uniform thickness of the walls of the seed crystal holder 100, thus transferring heat uniformly. For example, the seed crystal holder body 110 may be a cylinder, a cube, or a polygon, and correspondingly, the first inner cavity 112 may be a cylinder, a cube, or a polygon, etc. The connecting rod 120 may be a hollow to form a passageway to pass through the cooling medium. The cooling medium refers to a fluid (e.g., helium, argon, etc.) configured to cool the seed crystal holder. In some embodiments, the cooling medium may be an inert gas (e.g., room-temperature argon).

In some embodiments of the present disclosure, the passageway 121 within the connecting rod 120 is connected to the first inner cavity 112, thus the cooling medium may enter the first inner cavity 112 of the seed crystal holder body 110 through the passageway 121, thereby cooling the seed crystal holder body 110. Because a temperature of the molten liquid in the crucible 400 is high, the cooling of the seed crystal holder body 110 may increase the temperature gradient inside the seed crystal holder body 110, which helps to accelerate the generation of crystals.

In some embodiments, the seed crystal holder body 110 may also be provided with a first through hole 113 that is connected to the first inner cavity 112. The first through hole 113 may connect the first inner cavity 112 to a furnace cavity of a crystal growth furnace 200 for discharging the cooling medium from the first inner cavity 112 into the crystal growth furnace 200. The seed crystal holder body 110 may be provided with one or more first through holes 113. The shape of the first through hole 113 may be circular, oval, etc., or any other shape. In some embodiments, the first through hole 113 may be provided on any surface of the seed crystal holder body 110 other than the seed crystal bonding surface 111. As shown in FIG. 2A, a plurality of first through holes 113 are provided in an upper wall of the seed crystal holder body 110. The first inner cavity 112 is connected with the furnace cavity through the first through holes 113, which makes it possible for a cooling medium that has substantially lost its effectiveness to be discharged from the first inner cavity 112 through the first through holes 113, to enable a new cooling medium to continuously enter the seed crystal holder body 110 through the passageway 121, thereby improving cooling effect on the seed crystal holder body 110 and avoiding an increase in the internal pressure of the seed crystal holder body 110 to ensure the safe use of the seed crystal holder body 110.

In some embodiments, a cooling medium diffusion structure 114 may also be provided in the first inner cavity 112. The cooling medium diffusion structure 114 may be configured to assist in the diffusion of the cooling medium in the first inner cavity 112. For example, the cooling medium diffusion structure 114 may be a helical vane provided at an outlet of the passageway 121 in the first inner cavity 112. When the cooling medium enters the first inner cavity 112 through the passageway 121, the cooling medium may exert a force on the helical vane, thereby causing the helical vane to rotate, driving the incoming cooling medium to be dispersed with the helical vane at various places in the first inner cavity 112. In some embodiments of the present disclosure, through the cooling medium diffusion structure 114, the cooling medium in the first inner cavity 112 is evenly diffused, thereby ensuring that the various locations of the seed crystal holder body 110 may be evenly cooled, so that the seed crystal holder body 110 may be evenly cooled.

In some embodiments, the cooling medium diffusion structure 114 may include one or more tubular structures, and the one or more tubular structures are hollow. The one or more tubular structures may be round tubes, square tubes, or tubular structures with a cross-section of another shape.

When the cooling medium diffusion structure 114 includes a plurality of tubular structures, an inlet at one end of the plurality of tubular structures is connected to the passageway 121. The other end of the plurality of tubular structures may include a plurality of outlets, the plurality of outlets may respectively direct the cooling medium to a plurality of different locations in the first inner cavity 112, so that the cooling medium is uniformly diffused at the plurality of locations within the first inner cavity 112.

In some embodiments, the temperature of the seed crystal holder body 110 may also be detected by a temperature detection device (e.g., an external thermal imaging camera) to obtain corresponding temperature information (e.g., a thermal infrared image) during crystal generation. The seed crystal holder 100 may be in communication with a processor (not shown), and the processor may be configured to control the crystal generation. When the temperature information satisfies a preset temperature adjustment condition, the processor may determine, based on the temperature information, a location where a temperature adjustment is required. For example, the preset temperature adjustment condition may be that the temperature difference between the various regions in the seed crystal holder body 110 does not exceed a preset temperature difference threshold, and the processor may determine, based on the temperature information, a temperature distribution of the seed crystal holder body 110. When the temperature distribution characterizes the temperature difference between the temperature of a location in the seed crystal holder body 110 and the temperature of other regions to be greater than the temperature difference threshold, the processor may determine the location as a location requiring the temperature adjustment. The processor may determine, based on the location requiring the temperature adjustment, the corresponding cooling medium diffusion structure 114. The processor may control the input of the cooling medium to the corresponding cooling medium diffusion structure 114 to cool down the location, and continuously obtain temperature information corresponding to the seed crystal holder body 110 after the cooling process until the temperature information characterizes that the location requiring temperature adjustment does not satisfy the preset temperature adjustment condition. The processor may determine the corresponding cooling medium diffusion structure 114 by a temperature adjustment corresponding table and the location requiring the temperature adjustment. The temperature adjustment corresponding table may include a temperature adjustment location corresponding to each of the plurality of tubular structures in the cooling medium diffusion structure 114 (e.g., a location corresponding to each outlet of the plurality of tubular structures). Some embodiments of the present disclosure, by setting the cooling medium diffusion structure 114 into a plurality of tubular structures, may directionally adjust a localized temperature, avoiding localized high temperatures that may reduce the crystal quality. In addition, by monitoring the temperature of the seed crystal holder body 110, the temperature of the crystal generation may be automatically adjusted, thereby effectively improving the quality of the crystal generation.

When the cooling medium diffusion structure 114 includes one tubular structure, the tubular structure may be spirally wrapped around an inner wall of the first inner cavity 112, with an inlet at one end connecting to the passageway 121 and finally being exported to the crystal growth furnace 200. For example, the cooling medium diffusion structure 114 may be a square tube, and the square tube may be spirally wrapped around to fit completely around all inner walls or designated regions of the first inner cavity 112. Further, the tubular structure may also extend outside the crystal growth furnace 200. It is to be understood that, by entering the cooling medium into the first inner cavity 112 through the tubular structure, when the tubular structure is affixed to the inner wall of the first inner cavity 112, the cooling medium in the tubular structure may cool down the seed crystal holder body 110, and the cooling medium after cooling may continue to be exported out of the crystal growth furnace 200 through the tubular structure. Some embodiments of the present disclosure may make it possible to make the cooling medium not directly in contact with the seed crystal holder body 110 by the foregoing setting, but may still cool down the seed crystal holder body 110, to avoid the cooling medium from entering into the seed crystal holder body 110, which makes it difficult to clean, cause clogging, etc., or enter the crystal growth furnace 200, which may have an effect on the crystal growth. In addition, the controllability of performing the cooling process may also be improved by the foregoing setting. For example, it is possible to stop the continued inputting of the cooling medium into the tubular structure so that the current cooling medium may stay at a designated part. When it is necessary to renew the cooling medium, it is possible to continue inputting a new cooling medium into the tubular structure. As the new cooling medium enters, the used cooling medium may flow out of the tubular structure to guarantee the controllability of the cooling process.

In some embodiments, as shown in FIG. 2A, the cooling medium diffusion structure 114 may include a housing 1141. A second inner cavity 1142 is formed in the housing 1141, and the passageway 121 is connected to the second inner cavity 1142 to allow the cooling medium to enter into the second inner cavity 1142. The housing 1141 is provided with a plurality of diffusion holes 1143, and the diffusion holes 1143 are connected to the first inner cavity 112 and the second inner cavity 1142 so that the cooling medium in the second inner cavity 1142 may diffuse to the first inner cavity 1142 through the diffusion holes 1143. The housing 1141 may be shaped to fit the first inner cavity 112. The housing 1141 may be of various shapes, such as a rectangle, a square, a cylinder, or other shapes. The material of the housing 1141 may be graphite, high-temperature ceramic, stainless steel, or the like. In some embodiments of the present disclosure, the cooling medium may enter the second inner cavity 1142 through the passageway 121 and then enter the first inner cavity 112 through the diffusion holes 1143, which helps the cooling medium to diffuse quickly and avoids the cooling medium from accumulating at the outlet of the passageway 121.

In some embodiments, the seed crystal holder 100 may also include a cooling apparatus (not shown). The cooling apparatus is an apparatus for providing the cooling medium for the seed crystal holder body 110, which may deliver the cooling medium to the passageway 121. The cooling apparatus may output the cooling medium at a certain flow rate to cause the cooling medium to flow within the passageway 121 at a preset flow rate. For example, an outlet of the cooling apparatus may be connected to the passageway 121, and a power structure (e.g., a transfer pump) may also be provided within the cooling apparatus or the passageway to power the cooling medium, drive the cooling medium away from the cooling apparatus, and cause the cooling medium to flow at the preset flow rate within the passageway 121 toward the seed crystal holder body 110.

In some embodiments, the preset flow rate of the cooling medium is greater than 0.4 m/s. In some embodiments, the cooling medium may be at room temperature. In other embodiments, the cooling medium may be cooled to a certain temperature, such as 10° C., 15° C., 20° C., or the like. It is worth noting that due to the high temperature inside the crystal growth furnace 200 equipped with the seed crystal holder body 110, the cooling medium with a low flow rate may be heated up. In some embodiments of the present disclosure, by setting the preset flow rate to greater than 0.4 m/s, the cooling medium may be prevented from being heated, thereby ensuring the cooling effect of the cooling medium on the seed crystal holder body 110.

It will be appreciated that since the seed crystal holder body 110 is set up as a structure having the first inner cavity 112, the mass of the seed crystal holder body 110 is lightened, which may lead to wobbling. Thus, in some embodiments of the present disclosure, the seed crystal holder 100 may also include a weight-enhancing structure (not shown), which may be connected to the side of the seed crystal holder body 110 away from the connecting rod 120 by welding or bonding, etc. The weight-enhancing structure may be provided within the first inner cavity 112 or may be provided on the outer wall of the seed crystal holder body 110 (e.g., on any outer wall other than the seed crystal bonding surface 111). The weight-enhancing structure may be configured to increase a weight of the seed crystal holder body 110. The weight-enhancing structure may be a plurality of shaped structures, such as a plate structure, a ring structure, or the like. The weight-enhancing structure may be made of a variety of materials such as stainless steel, high-temperature ceramics, tungsten alloy, or the like. In some embodiments of the present disclosure, by connecting the weight-enhancing structure to the seed crystal holder body 110, the weight of the seed crystal holder body 110 may be increased to avoid the seed crystal holder body 110 from shaking during the crystal growth process, which helps the stable generation of crystals, thereby ensuring the quality of the crystals.

In some embodiments, the seed crystal holder 100 may also include a cooling structure (not shown), which may be provided on the connecting rod 120 for cooling the cooling medium within the passageway 121. The cooling structure may include a plurality of types, e.g., condensers, expansion valves, etc., or any combination thereof. The cooling structure may be an annular structure attached to an inner wall of the connecting rod 120. As the cooling medium passes through the passageway 121, the cooling structure may cool down the cooling medium within the passageway 121 by lowering the pressure of the cooling medium and/or exchanging heat with the cooling medium. In some embodiments of the present disclosure, by providing the cooling structure, the temperature of the cooling medium may be lowered, the cooling medium may be avoided to be heated too quickly by the surrounding environment, thereby ensuring that the cooling medium enters the first inner cavity 112 in a state with a low temperature, so that the heat of the seed crystal holder body 110 may be absorbed quickly and efficiently in the first inner cavity 112, which helps to improve the cooling effect on the seed crystal holder body 110.

In some embodiments, the cooling structure includes a cooling circuit 123, and the cooling circuit 123 conveys a cooling fluid for cooling the cooling medium. In some embodiments, the cooling circuit 123 is provided outside the connecting rod. As shown in FIG. 2B and FIG. 2C, the cooling structure may include a cooling sleeve 124. The cooling sleeve 124 is socketed to the connecting rod 120, and the cooling circuit 123 is provided on the cooling sleeve 124. In some embodiments, the cooling fluid may be a coolant, for example, water. In some embodiments, the cooling loop 123 may include an input channel and an output channel. In some embodiments, the input channel and the output channel may be parallel to the passageway 121 that carries the cooling medium. In other embodiments, the input channel and the output channel may be in the form of a helix arranged around the passageway 121 conveying the cooling medium for well cooling of the cooling medium.

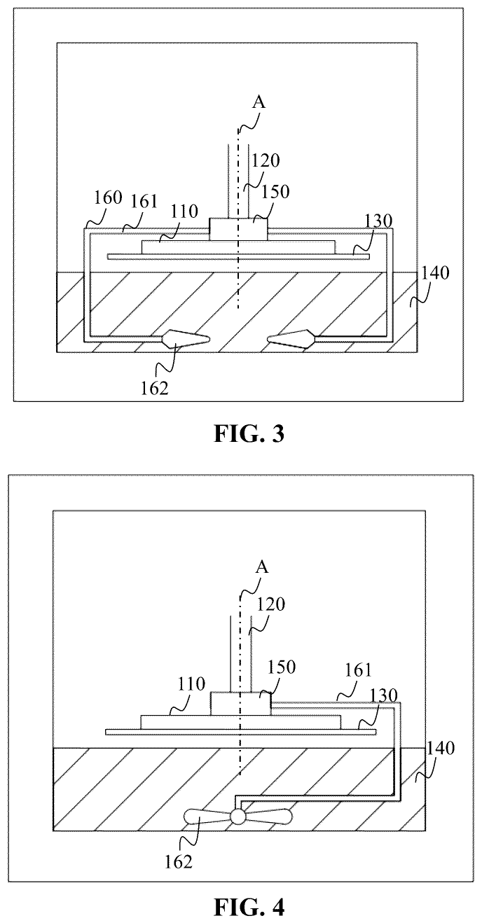

In some embodiments, as shown in FIG. 3, the seed crystal holder 100 may also include a driving mechanism 150 and a stirring mechanism 160.

The driving mechanism 150 is a mechanism that converts other energy sources into mechanical energy and generates kinetic energy. The driving mechanism 150 may include a plurality of types, for example, a motor, a pneumatic source, a hydraulic source, or the like. The driving mechanism 150 may be connected to the other end of the connecting rod 120. The other end of the connecting rod 120 refers to an end of the connecting rod 120 away from the seed crystal holder body 110. The driving mechanism 150 may drive the seed crystal holder body 110 to rotate, via the connecting rod 120, around an axis A of the connecting rod 120. By setting the driving structure 150, the seed crystal holder 100 may rotate at a desired speed during the crystal growth process to ensure stable crystal growth.

The stirring mechanism 160 may be configured to stir a molten liquid 140 for crystal growth. As shown in FIG. 3 to FIG. 4, the stirring mechanism 160 may be connected to the seed crystal holder body 110, and in the process of driving the seed crystal holder 100 by the driving mechanism 150, the stirring mechanism 160 is configured to stir the molten liquid 140. The stirring mechanism 160 may be of a plurality of shapes, such as a rod, a plate, or various other irregular shapes. It should be noted that the stirring mechanism 160 needs to reach below the liquid level of the molten liquid 140 during the crystal growth process to achieve the stirring of the molten liquid 140.

During the crystal growth process, the seed crystal 130 and the molten liquid 140 are only in contact at the liquid surface, and thus the molten liquid 140 has less agitation and a low flow rate, which leads that the molten liquid 140 does not have a sufficiently homogeneous mass transfer, which leads to an effect on the crystal growth quality. In some embodiments of the present disclosure, the seed crystal holder body 110 is driven to rotate around the axis A of the connecting rod 120 by the driving mechanism 150, and the rotation of the seed crystal holder body 110 may drive the stirring mechanism 160 to rotate around the axis A of the connecting rod 120, thereby realizing the stirring of the molten liquid 140, which may increase the flow rate of the molten liquid 140, improve the mass transfer route of the key substances in the molten liquid 140, ensure the homogeneous mass transfer, and improve the efficiency of the crystal growth.

In some embodiments, as shown in FIG. 4, the stirring mechanism 160 may include a mounting rod 161 and a stirring paddle 162. One mounting rod 161 corresponds to one stirring paddle 162. The stirring paddle 162 may include a plurality of shapes, such as, for example, a slurry stirring paddle, a disc turbine paddle, or the like. The stirring paddle 162 is located on the side of the seed crystal bonding surface 111 away from the connecting rod 120. The stirring paddle 162 may extend inside the molten liquid 140 to stir the molten liquid 140. As shown in FIG. 3 and FIG. 4, the stirring mechanism 160 may include a mounting rod 161 and a stirring paddle 162, with one end of the mounting rod 161 being connected to the seed crystal holder body 110 and the other end of the mounting rod 161 being connected to the stirring paddle 162. The driving mechanism 150 may drive the seed crystal holder body 110 to rotate along the axis A, which in turn drives the mounting rod 161 to rotate along the axis A. The rotation of the mounting rod 161 may drive the stirring paddle 162 connected thereto to move to cause the stirring paddle 162 to stir the molten liquid 140.

In some embodiments, there may be a plurality of stirring mechanisms 160, with the plurality of stirring mechanisms 160 being provided around the seed crystal holder body. In some embodiments, the stirring mechanisms 160 may be arranged in a centrally symmetric row relative to the axis A. As shown in FIG. 3, the seed crystal holder 100 may include two stirring mechanisms 160, and the two stirring mechanisms 160 are arranged in a centrosymmetric symmetrical row based on the axis A.

In some embodiments, there may also be a single mixing mechanism 160. As shown in FIG. 4, the seed crystal holder 100 may include a single stirring mechanism 160, and the stirring paddle 162 of the single stirring mechanism 160 may include a plurality of blades. During rotation of the stirring mechanism 160 about the axis A, the blades of the stirring paddle 162 may rotate around the center of the stirring paddle 162, which helps to increase the flow rate of the molten liquid 140.

In some embodiments, the material of the stirring mechanism 160 may be one or more of a tungsten alloy or a high temperature ceramic. The stirring mechanism 160 made of tungsten alloy, high temperature ceramics, or the like, may have high stability in the high temperature molten liquid 140, which effectively improves the service life of the stirring mechanism 160.

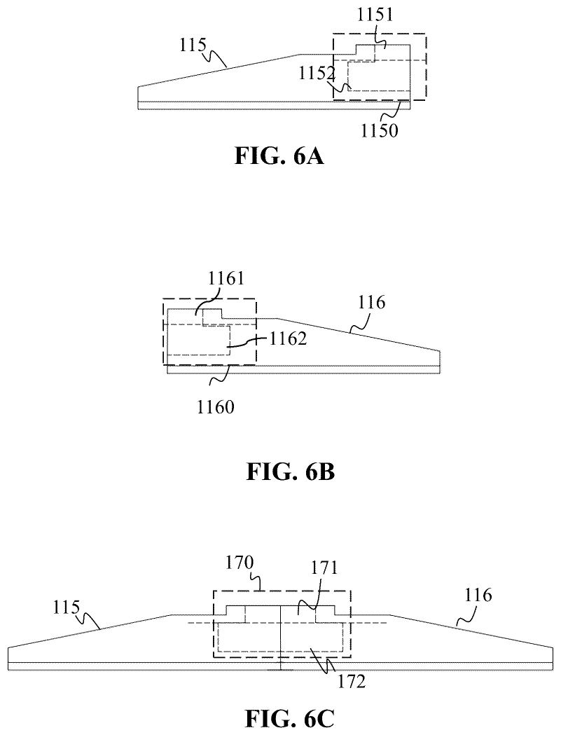

In some embodiments, the seed crystal holder body 110 includes at least two subsections. As shown in FIG. 6A, FIG. 6B, and FIG. 6C, the seed crystal holder body 110 may include two subsections, i.e., a first subsection 115 and a second subsection 116. The seed crystal holder body may also include three subsections, four subsections, or some other count of subsections. An embodiment in which the seed crystal holder body 110 includes two subsections is described below.

As shown in FIG. 6C, the first subsection 115 and the second subsection 116 may be spliced to form the seed crystal holder body 110. It will be appreciated that the seed crystal holder body 110 may be of various shapes, such as a table shape, a cylindrical shape, etc., and the subsections thereof may be of a shape corresponding to the shape of the seed crystal holder body 110 after being split from the seed crystal holder body 110. Taking the example that the seed crystal holder body 110 is in the shape of a truncated cone or a cylinder, the first subsection 115 and the second subsection 116 may be in the shape of a semi-cylinder or semi-truncated cone.

In some embodiments, the shapes and sizes of the different subsections of the seed crystal holder body 110 may also be different. Exemplarily, the first subsection 115 may be a three-quarter cylinder and the second subsection 116 may be a quarter cylinder. That is, an area of a cross-section of the first subsection 115 perpendicular to the axis of the first subsection 115 is greater than an area of a cross-section of the second subsection 116 perpendicular to the axis of the second subsection 116. For example, the cross-section of the first subsection 115 perpendicular to the axis of the first subsection 115 is enclosed by superior arcs and straight lines, and the cross-section of the second subsection 116 perpendicular to the axis of the second subsection 116 is enclosed by inferior arcs and straight lines.

The splicing of the at least two subsections of the seed crystal holder body 110 refers to placing and combining the at least two subsections together in a preset position to splice them together to form a complete seed crystal holder body 110. The at least two subsections of the seed crystal holder body 110 may be spliced in a plurality of ways. For example, the at least two subsections may be simply placed together in a preset position. As another example, any two adjacent subsections are provided with a positioning groove in one of the two subsections, and a positioning hump in the other, and the adjacent subsections may be fixed by placing the positioning hump into the positioning groove, thereby combining the at least two subsections together.

In some embodiments, a half-groove is provided on each of the at least two subsections of the seed crystal holder body 110. It should be noted that the half-groove may be understood to be a portion of a complete snapping groove. The splicing of the at least two subsections causes the half-groove on each of the at least two subsections to be spliced to form a complete snapping groove 170. That is, the subsections are part of the seed crystal holder body 110 and the half-groove is part of the snapping groove 170. By splicing the subsections together into the seed crystal holder body 110, the snapping groove into which the half-groove is spliced is also realized. For example, a first half-groove 1150 may be provided on the first subsection 115, a second half-groove 1160 may be provided on the second subsection 116, and the first subsection 115 and the second subsection 116 are spliced so that the first half-groove 1150 and the second half-groove 1160 are spliced so to form the snapping groove 170.

As shown in FIG. 5 and FIGS. 6A-6C, the first half-groove 1150 is located in the first subsection 115 and is provided at an end of the first subsection 115 that is connected with the connecting rod 120. The second half-groove 1160 is disposed in the second subsection 116 and is provided at an end of the second subsection 116 that is connected with the connecting rod 120. In some embodiments, the structures of the second half-groove 1160 and the first half-groove 1150 may be the same and are symmetrical with the axis A of the connecting rod 120. In some other embodiments, the structures of the first half-groove 1150 and the second half-groove 1160 may be different. The first half-groove 1150 and the second half-groove 1160 are spliced together to form the snapping groove 170, which allows for the connecting rod 120 and the snapping structure 118 to be set within the snapping groove.

In some embodiments, the seed crystal holder 100 may also include a locking structure 117 and a snapping structure 118.

As shown in FIG. 5, the snapping structure 118 is provided at the end of the connecting rod 120 that is connected to the seed crystal holder body 110. The snapping structure 118 may be snapped into the snapping groove to enable the connecting rod 120 to be tightly connected to the seed crystal holder body 110 by the snapping structure 118. The snapping structure 118 may include a plurality of three-dimensional structures (e.g., a square, a cylinder, etc.) and is located at the end of the connecting rod 120 that is connected to the seed crystal holder body 110. The snapping structure 118 may be understood to be capable of being accommodated within the snapping groove 170 and not being disengaged from the snapping groove 170 after being snapped. The snapping structure 118 may be snapped to the snapping groove 170 in a variety of ways, as described below.

As shown in FIG. 5, the locking structure 117 is provided on the outer wall of the seed crystal holder body 110, and may fix the at least two subsections (e.g., the first subsection 115 and the second subsection 116) that are spliced. In some embodiments, the locking structure 117 may include a bolt, a nut, and a raised structure. The raised structure is provided on the first subsection 115 and the second subsection 116 and is provided with threaded holes. The bolt may pass through the threaded holes on the raised structure of the first subsection 115 and the threaded holes on the raised structure of the second subsection 116, and the bolt may be fixed to the threaded holes by the nut, thereby fixing the first subsection 115 and the second subsection 116.

It is understood that in the process of crystal growth, the seed crystal holder body 110 and the connecting rod 120 are often connected by screw threads, and the screw-connected portion may produce a cavity due to the presence of a relief groove. Thus, gas may enter into the cavity, which may affect the uniform change in the temperature gradient of the seed crystal holder body 110, thereby inducing the formation of voids on the crystal growth surface. Therefore, in some embodiments of the present disclosure, by setting the seed crystal holder body 110 to include at least two subsections, the locking structure 117 fixing the at least two subsections to each other, and snapping the snapping structure 118 to the snapping groove, the seed crystal holder body 110 may be tightly connected to the connecting rod 120 without the existence of a space capable of entering gas. Then, the problem of the relief groove is solved, which not only makes the temperature of the seed crystal holder body 110 change uniformly but also facilitates the separation of the crystal holder later (by unlocking the locking structure 117), thereby greatly improving the quality of the prepared crystals.

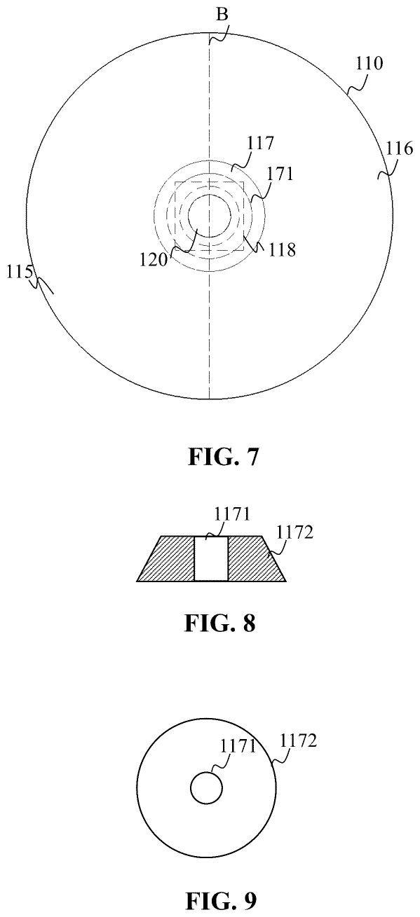

In addition, it is worth stating that an ablation of the seed crystal holder body 110 may realize a separation of the crystals from the seed crystal holder body 110 after crystal growth, and the speed of the ablation depends on the orientation of the concave threads at the top of the seed crystal holder body 110 in the ablation apparatus. The speed of the ablation may slow down after about one-third of 12 hours of the ablation in an upwind direction when the threaded holes at the top of the seed crystal holder body 110 are free of adherents. In the above embodiment of the present disclosure, a combination surface occurs at the splicing site of the plurality of subsections. As shown in FIG. 7, a combination surface B exists at the splicing site of the first subsection 115 and the second subsection 116, and the combination surface B may play a certain guiding role during the ablation process to accelerate the speed of the later ablation, which helps to improve the efficiency of the separation between the crystal and the seed crystal holder.

In some embodiments, the at least two subsections of the seed crystal holder body 110 include a first subsection 115 and a second subsection 116 of the same structure, the first subsection 115 and the second subsection 116 being symmetrically provided with the axis of the connecting rod as the axis of symmetry. In other embodiments, when the seed crystal holder body includes three or more subsections, each of the subsections may be structurally the same and uniformly and symmetrically arranged.

Taking the example of the seed crystal holder body including two subsections, such as FIG. 6A, FIG. 6B, FIG. 6C, and FIG. 7, the structure of the first subsection 115 and the second subsection 116 may be the same, and the first subsection 115 and the second subsection 116 may be symmetrically provided with the axis A of the connecting rod 120 as the axis of symmetry.

In some embodiments of the present disclosure, the at least two subsections of the seed crystal holder body 110 are structurally identical and symmetrically arranged, which may facilitate manufacturing and may enhance the efficiency of assembly of the seed crystal holder body 110.

As shown in FIG. 5 to FIG. 7, the snapping groove includes a first groove body 171 and a second groove body 172 arranged in a direction of the axis A of the connecting rod 120. The first groove body 171 is closer to the seed crystal bonding surface than the second groove body 172. An area of the first groove body 171 along the cross-section perpendicular to the axis A of the connecting rod 120 is larger than an area of the second groove body 172 along the cross-section perpendicular to the axis A of the connecting rod 120. An area of the snapping structure 118 along the cross-section perpendicular to the axis A of the connecting rod 120 is greater than an area of the connecting rod 120 along the cross-section perpendicular to the axis A of the connecting rod 120.

The first groove body 171 is configured to fix the snapping structure 118, and the second groove body 172 is configured to accommodate the connecting rod 120. Correspondingly, the area of the snapping structure 118 along the cross-section perpendicular to the axis A of the connecting rod 120 is greater than the area of the connecting rod 120 along the cross-section perpendicular to the axis A of the connecting rod 120, the shape of the first groove body 171 is adapted to the shape of an end of the snapping structure 118 close to the snapping structure 118, and the end of the connecting rod 120 close to the snapping structure 118 is provided within the second groove body 172, to enable the snapping structure 118 to fix the relative position of the connecting rod 120 and the seed crystal holder body 110. In some embodiments of the present disclosure, the connecting rod 120 is inlaid with the seed crystal holder body 110 by the snapping structure 118, which helps to avoid the aforementioned problem of voids due to the existence of the relief groove and ensures a stable connection between the connecting rod 120 and the seed crystal holder body 110.

The following is an example of at least two subsections including a first subsection 115 (including a first half-groove 1150 thereon) and a second subsection 116 (including a second half-groove 1160 thereon). As in FIG. 6A, the first half-groove 1150 may be divided into a first upper half-groove 1151 and a first lower half-groove 1152. As in FIG. 6B, the second half-groove 1160 may be divided into a second upper half-groove 1161 and a second lower half-groove 1162. As in FIG. 6C, the first upper half-groove 1151 and the second upper half-groove 1161 may be spliced to form the first groove body 171, and the first lower half-groove 1152 and the second lower half-groove 1162 may be spliced to form the second groove body 172.

In some embodiments, the snapping structure 118 may be in a polyhedral shape. As shown in FIG. 7, the cross-section of the snapping structure 118 may be a square. In some embodiments of the present disclosure, by setting the snapping structure 118 in the shape of a polyhedron, it is possible to ensure the synchronized rotation of the snapping structure 118 when the seed crystal holder body 110 rotates. It will be appreciated that the snapping structure 110 may also be cylindrical if the seed crystal holder body 110 does not rotate when generating the crystals.

It should be noted that the snapping groove 170 and the snapping structure 118 may be of various shapes, as long as it is possible to realize that the snapping structure 118 is snapped in the snapping groove 170 and does not detach from the snapping groove 170. Merely by way of example, the snapping groove 170 may be a trapezoidal groove, which means that the area of the cross-section perpendicular to the axis A of the snapping groove 170 varies at different positions of the snapping groove 170. The closer to the seed crystal bonding surface 111, the larger the area of the cross-section of the snapping groove 170. Correspondingly, the snapping structure 118 may also be a quadrangular prism.

As shown in FIG. 8 to FIG. 9, the locking structure 117 may include an annular groove 1171 and a locking ring 1172. The annular groove 1171 may be provided around the outer wall of the seed crystal holder body 110, and the locking ring 1172 is socketed outside the at least two subsections (e.g., the first subsection 115 and the second subsection 116) after splicing and is provided within the annular groove 1171. In some embodiments, the outer wall of the annular groove 1171 is provided with external threads and the inner wall of the locking ring 1172 is provided with internal threads. The locking ring 1172 is connected to the annular groove 1171 by a threaded connection to allow the locking ring 1172 to be set into the annular groove. Furthermore, the external threads on the outer wall of the annular groove 1171 do not extend beyond the top of the seed crystal holder body 110, avoiding the inability to be hot pressed at a later stage.

The bottom of the locking ring 1172 in the locking structure 117 and the annular groove 1171 may be affixed to the seed crystal holder body 110. The locking ring 1172 surrounds the seed crystal holder body 110 at the outer wall of the seed crystal holder body 110, which may lock the at least two subsections that are spliced (e.g., the first subsection 115 and the second subsection 116), provide a fixed restriction on the seed crystal holder body 110, realize the fixation of the at least two subsections, and thus ensure a tight connection between the seed crystal holder body 110 and the connecting rod 120, and the locking operation is simple and convenient.

In some embodiments, the seed crystal holder 100 may further include a protective bracket 180 for protecting the seed crystal holder body 110. As shown in FIG. 10, the seed crystal holder 100 may further include a protective bracket 180. The protective bracket 180 is annular and is provided with a holding cavity 184 matched with the shape of the seed crystal holder body 110, and the protective bracket 180 may be provided around the seed crystal holder body 110. In addition, the protective bracket 180 may also surround an end of the seed crystal holder body 110 that is connected to the connecting rod 120. The holding cavity 184 may hold the seed crystal holder body 110, and the seed crystal holder body 110 may closely fit the inner wall of the holding cavity 184. The protective bracket 180 may be made of graphite material. A side of the protective bracket 180 close to the connecting rod 120 is an upper surface, the upper surface of the protective bracket 180 is provided with a third through hole, and the shape of the third through hole may match the shape of the connecting rod 120 (e.g., if the connecting rod 120 is a cylindrical rod, the third through hole may be a cylindrical hole). The third through hole is in communication with the holding cavity 184, and a diameter of the third through hole is in correspondence with an outside diameter of the outer wall of the connecting rod 120 along an axial direction of the connecting rod 120. The third through hole may be provided with the axis A of the connecting rod 120, and the connecting rod 120 may pass through the third through hole on the upper surface of the protective bracket 180 and be connected to the seed crystal holder body 110 in a plurality of ways (e.g., a threaded connection, a snap connection, the means described in the embodiments above, etc.).

It is worth stating that, when the seed crystal 130 on the top is lifted and grown, the seed crystal holder body 110 may be wrapped with volatiles at a place where the seed crystal holder body 110 is affixed to the seed crystal 130, and there may be an adhesion layer on the surface of the seed crystal holder body 110, which may not only result in the inability of the crystal holder to separate directly, but also result in that the adhesion layer affects the absorption and releases of heat by the seed crystal support 110, thereby affecting the growth and quality of the crystal. In some embodiments of the present disclosure, by surrounding the seed crystal support 110 with the protective bracket 180, the adhesion layer on the surface of the seed crystal holder body 110 may be avoided, and axial and radial temperature gradients of the seed crystal holder body 110 may be controlled, thereby improving the quality and morphological stability of the crystal.

In some embodiments, the seed crystal holder 100 may further include a first protective sleeve 181, the first protective sleeve 181 is annular and is provided outside of the connecting rod 120, and the first protective sleeve 181 is provided between the connecting rod 120 and the protective bracket 180. The first protective sleeve 181 may be configured to avoid volatiles from entering between the seed crystal holder body 110 and the connecting rod 120, and avoid volatiles from entering between the protective bracket 180 and the connecting rod 120. As shown in FIG. 10, the first protective sleeve 181 may be an annular cylinder that is hollow inside, and the inner wall of the first protective sleeve 181 wraps the connecting rod 120, the outer wall of the first protective sleeve 181 is connected to the surface of the protective bracket 180, and the bottom surface is embedded in the protective bracket 180. The upper surface of the protective bracket 180 may be provided with an annular groove, and the size of the annular groove is adapted to the first protective sleeve 181 to allow the outer wall and the bottom surface of the first protective sleeve 181 to fit in the annular groove.

As shown in FIG. 10, the connecting rod 120 may include a first outer diameter section r₃ and a second outer diameter section r₂ along the axial direction of the connecting rod 120. The outer diameter of the first outer diameter section r₃ is smaller than the outer diameter of the second outer diameter section r₂, and the first outer diameter section r₃ is closer to the seed crystal holder body 110 than the second outer diameter section r₂. Correspondingly, the first protective sleeve 181 includes a first inner diameter section r₄ and a second inner diameter section r₁ along the axial direction of the connecting rod 120. An inner diameter of the first inner diameter section r₄ is smaller than an inner diameter of the second inner diameter section r₁, and the first inner diameter section r₄ is closer to the seed crystal holder body 110 than the second inner diameter section r₁. The first inner diameter section r₄ may match the first outer diameter section r₃, and the second inner diameter section r₁ may match the second outer diameter section r₂. As shown in FIG. 10, the first protective sleeve 181 may connect the connecting rod 120 to the protective bracket 180, and the first inner diameter section r₄ and the second inner diameter section r₁ of the first protective sleeve 181 match the first outer diameter section r₃ and the second outer diameter section r₂ of the connecting rod 120, respectively. The outer wall of the first protective sleeve 181 is connected to the protective bracket 180, and the bottom surface is embedded in the protective bracket 180.

In some embodiments of the present disclosure, connecting the connecting rod 120 to the protective bracket 180 by the first protective sleeve 181 may effectively prevent volatiles from entering between the seed crystal holder body 110 and the connecting rod 120, and prevent volatiles from entering between the protective bracket 180 and the connecting rod 120 causing adhesion, and facilitating the realization of crystal cutting and separation or ablation separation.

In some embodiments, a second protective sleeve 182 may be provided on a surface of a side of the protective bracket 180 away from the connecting rod 120, the second protective sleeve 182 is annular and is embedded within the protective bracket 180, and the second protective sleeve 182 is provided around the holding cavity 184.

As shown in FIG. 10, when the seed crystal bonding surface 111 is bonded with the seed crystal 130, the end of the second protective sleeve 182 away from the connecting rod 120 may be affixed to the side of the seed crystal 130 close to the connecting rod 120 to prevent volatiles from entering between the seed crystal holder body 110 and the connecting rod 120, and between the protective bracket 180 and the connecting rod 120, causing adhesion.

Some embodiments of the present disclosure, the second protective sleeve 182 may prevent the molten liquid 140 volatiles from entering the seed crystal holder body 110 to corrode the graphite paper or the seed crystal holder body 110 and also ensure that the seed crystal 130 is not subjected to force when being lifted and pulled, thus avoiding the seed crystal 130 from falling off.

In some embodiments, a ratio of a height of the second protective sleeve 182 along the axial direction of the connecting rod 120 to a diameter of the seed crystal bonding surface 111 of the seed crystal holder body 110 is 3:150. By setting the ratio of the height of the second protective sleeve 182 in the axial direction of the height of the second protective sleeve 182 to the diameter of the seed crystal bonding surface 111, it may be ensured that the dimension of the second protective sleeve 182 may be effective in serving as protection.

In some embodiments, a first groove 183 may be provided on the surface of the side of the protective bracket 180 back away from the connecting rod 120. The diameter of the first groove 183 is larger than the diameter L of an opening of the side of the holding cavity 184 back away from the connecting rod 120. As shown in FIG. 10, the first groove 183 includes a connecting portion 1831 connected to the opening and an annular portion 1832 encircling the connecting portion. A bottom surface of the annular portion 1832 (e.g., the upper surface of the first groove) is located in a same plane as the seed crystal bonding surface 111. The annular portion 1832 of the first groove 183 is adapted in shape with the second protective sleeve 182, and the second protective sleeve 182 is provided on the bottom surface of the annular portion 1832 of the first groove 183.

In embodiments of the present disclosure, the first groove 183 enables the second protective sleeve 182 to be embedded into the protective bracket, which may further prevent volatiles from entering between the seed crystal holder body 110 and the connecting rod 120, and prevent volatiles from entering between the protective bracket 180 and the connecting rod 120, in which entering the volatiles may cause adhesion. In addition, since the bottom surface of the annular portion 1832 (e.g., the upper surface of the first groove) is located in the same plane as the seed crystal bonding surface 111, a portion of the seed crystal may be bonded to the bottom surface of the annular portion 1832 and fit to the second protective sleeve 182. The dimension of the first groove 183 may be substantially matched with the dimension of the seed crystals, which may also facilitate to a certain extent the operator in determining the bonding position of the seed crystals to ensure the concentricity of the seed crystal and the seed crystal holder 100.

In some embodiments, the diameter of the first groove 183 is larger than the diameter of the opening by 5 mm-10 mm to facilitate the setting of the annular portion, and to facilitate the embedding of the second protective sleeve 182 into the protective bracket 180, which also ensures that the seed crystal may be more stably bonded.

In some embodiments, a graphite paper 119 may be bonded to the seed crystal bonding surface 111. The graphite paper 119 may be configured to fix the seed crystal 130. The dimension of the graphite paper 119 may be adapted to the seed crystal bonding surface 111 to allow the graphite paper 119 to fully fit on the seed crystal bonding surface 111. The graphite paper 119 may be bonded to the seed crystal bonding surface 111 by a hot melt adhesive. The graphite paper 119 projects from the lower surface of the second protective sleeve 182 in a direction away from the connecting rod 120 (e.g., in direction D as shown in FIG. 10). For example, the graphite paper 119 may project 0.1 mm-0.2 mm from the surface of the side of the second protective sleeve 182 away from the connecting rod 120 in a direction away from the connecting rod 120 to ensure that the seed crystal 130 may project in the direction away from the connecting rod 120 on the lower surface of the protective bracket 180. It is worth stating that the seed crystal 130 starts to grow at a certain rate after contacting the molten liquid 140. As time passes, circumstances such as the crucible wall begins to corrode, the molten liquid 140 evaporates, etc., may cause the liquid level of the molten liquid 140 to gradually decrease, and the relative speed of the seed crystal 130 deviating from the liquid level of the melt 140 gradually accelerates, thereby preventing the crystal from growing according to a established lifting speed. In some embodiments of the present disclosure, by setting the graphite paper on the surface of the protruding side of the second protective sleeve 182 away from the connecting rod 120, it is possible to make the seed crystal 130 comes into full contact with the liquid surface of the molten liquid 140, and the crystal may be grown according to a developed lifting speed.

In some embodiments, the seed crystal holder 100 may be provided in a seed crystal bonding device 30, and the seed crystal bonding device 30 may be configured to bond the seed crystal 130 based on the seed crystal holder 100. The seed crystal bonding device 30 may be configured to bond the seed crystal 130.

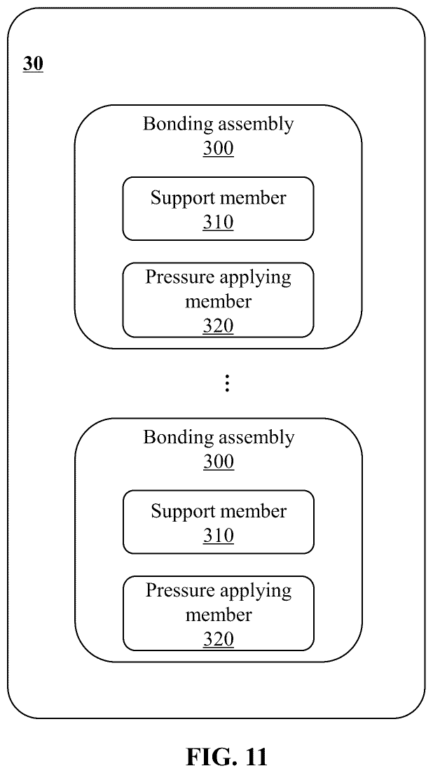

FIG. 11 is a diagram illustrating exemplary modules of a seed crystal bonding device according to some embodiments of the present disclosure.

As shown in FIG. 11, the seed crystal bonding device 30 may include one or more bonding assemblies 300, and the one or more bonding assemblies 300 may include a support member 310 and a pressure applying member 320.

The support member 310 may be configured to support the seed crystal holder 100. For example, the support member 310 may be configured to support the seed crystal holder body 110. As another example, the support member 310 may also be configured to support the seed crystal holder body 110 and the connecting rod 120. The support member 310 may include a support frame made of metal, stainless steel, or the like, and the structure to be supported in the seed crystal holder 100 may be fixed to the support frame.

The pressure applying member 320 may apply pressure to the seed crystal 130 and/or seed crystal holder 100, which may biaxially press the seed crystal holder 100 and the seed crystals 130 on the seed crystal holder 100.

In some embodiments of the present disclosure, by the seed crystal bonding device 30 provided with one or more bonding assemblies 300, not only the seed crystal holder 100 may be biaxially pressed with the seed crystal 130 during the bonding process, but also the seed crystal holder 100 may be fixed, thereby making the bonding process stable, and improving the bonding effect of the seed crystal 130.

As shown in FIG. 12, the seed crystal bonding device 30 may further include a vacuum furnace cavity 31, a vacuum assembly 32, a column 33, a motor 34, a silk rod 35, a pressure column 36, a support assembly 37, a heating assembly 38, and a lower pressure plate 39. The vacuum furnace cavity 31 may be a place where the seed crystal 130 is bonded, and the vacuum assembly 32 may be configured to evacuate the vacuum furnace cavity 31. The column 33 may be provided on the top of the vacuum furnace cavity 3, and the motor 34 may be fixed (e.g., bolted or welded) on the column 33. The silk rod 35 and the motor 34 may be rotationally connected, and the silk rod 35 may rotate around the center axis and thus move up and down when the motor 34 is operating. The upper end of the pressure column 36 may be connected to the lower end of the silk rod 35, and the pressure column 36 may move up and down when the silk rod 35 rotates and moves up and down, and the pressure column 36 may apply pressure to the bonding assembly 300 when the pressure column 36 moves down. The support assembly 37 may be placed at the bottom of the seed crystal bonding device 30 to support the heating assembly 38 and the lower pressure plate 39. The heating assembly 38 may be provided between the support assembly 37 and the lower pressure plate 39 to provide heat required for bonding the seed crystal 130. The upper surface of the heating assembly 38 may be placed with the lower pressure plate 39, and the upper portion of the lower pressure plate 39 may be placed with the bonding assembly 300 to cooperate with the pressure column 36 in applying pressure to the bonding assembly 300 to bond the seed crystal 130 on the seed crystal holder 100. The seed crystal holder 100 and the seed crystal 130 may be placed in the bonding assembly 300, and the vacuum furnace cavity 31 is evacuated and the pressure is applied to the bonding assembly 300 by other components (e.g., the vacuum assembly 32, the pressure column 36, the heating assembly 38, and the lower pressure plate 39) within the seed crystal bonding device 30 to bond the seed crystal 130 to the seed crystal holder 100 for crystal growth.

In some embodiments, the support member 310 includes a first pressure member 380 and a second pressure member 390, and the pressure applying member 320 includes a first pressure plate 322. The second pressure member 390 is nested with the first pressure member 380. During the bonding and fixing process of the seed crystal 130, the seed crystal 130 is placed on the upper surface of the second pressure member 390, the seed crystal holder 100 is placed on the upper surface of the seed crystal 130, and the first pressure disk 322 may apply pressure to the seed crystal holder 100 so that the seed crystal 130 may be bonded to the seed crystal holder 100.

The sidewall of the first pressure member 380 may include at least one first air venting hole 383. The at least one first air venting hole 383 may run horizontally through the sidewall of the first pressure member 380. The at least one first air venting hole 383 may be evenly and symmetrically distributed across the sidewall of the first pressure member 380. The at least one first air venting hole 383 may be located at the same height in the vertical direction.

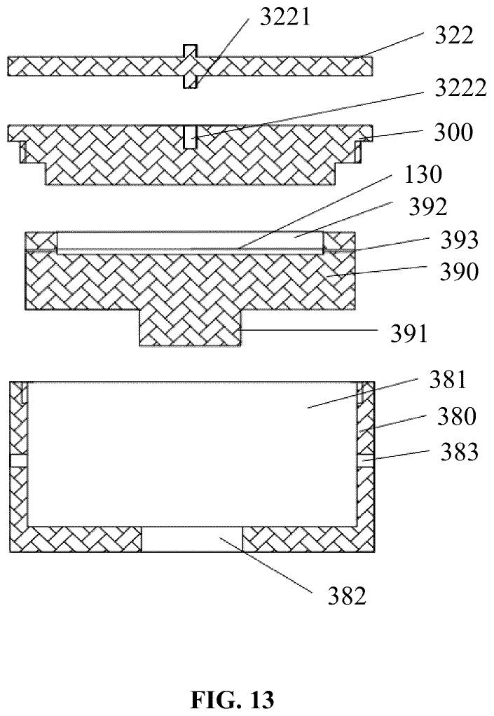

As shown in FIG. 13, the first pressure member 380 may be shaped as a column having an internal cavity 381 (e.g., a cylinder, a cube, or a polygon with an internal cavity). The shape of the internal cavity of the first pressure member 380 may be a cylinder, a cube, or a polygon. The shape of the second pressure member 390 may be a cylinder, a cube, or a polygon. The shape and/or dimension of the internal cavity of the first pressure member 380 is adapted to the shape and/or dimension of the second pressure member 390 such that the second pressure member 390 may be provided within the first pressure member 380 without substantial movement (e.g., the amount of movability is less than a preset threshold). Specifically, the shape and/or dimension of the internal cavity of the first pressure member 380 being adapted to the shape and/or dimension of the second pressure member 390 may be that the shape of the internal cavity of the first pressure member 380 is consistent or substantially consistent with the shape of the outer wall of the second pressure member 390, and the dimension of the internal cavity of the first pressure member 380 is slightly larger than the dimension of the outer wall of the second pressure member 390 and a difference between the dimension of the internal cavity of the first pressure member 380 and the dimension of the outer wall of the second pressure member 390 is less than a first preset dimension threshold (e.g., 3 mm). The first preset dimension threshold may be a default value or may be adjusted depending on the situation. For example, if the shape of the outer wall of the second pressure member 390 is cylindrical, the shape of the internal cavity of the first pressure member 380 is also cylindrical, and the diameter of the internal cavity of the first pressure member 380 is slightly larger than the diameter of the outer wall of the second pressure member 390. For example, the diameter of the outer wall of the second pressure member 390 is 15 cm and the diameter of the internal cavity of the first pressure member 380 is 15.3 cm.

By setting the shape and/or dimension of the internal cavity of the first pressure member 380 to be adapted with the shape and/or dimension of the second pressure member 390, so that the second pressure member 390 may be placed inside the first pressure member 380 without substantial movement, and the first pressure member 38 is securely nested with the second pressure member 390.

In some embodiments, a bottom of the first pressure member 380 includes a second through hole 382, and a bottom of the second pressure member 390 includes a first hump 391. The first hump 391 cooperates with the second through hole 382 to realize a nested connection of the first pressure member 380 and the second pressure member 390.

As shown in FIG. 13, the shape of the second through hole 382 may be a cylinder, a cube, or a polygon. For case of installation, the second through hole 382 may be cylindrical. In some embodiments, the diameter of the second through hole 382 may be within a range of 5 mm-150 mm. In some embodiments, the diameter of the second through hole 382 may be within a range of 8 mm-140 mm. In some embodiments, the diameter of the second through hole 382 may be within a range of 10 mm-130 mm. In some embodiments, the diameter of the second through hole 382 may be within a range of 20 mm-120 mm. In some embodiments, the diameter of the second through hole 382 may be within a range of 30 mm-110 mm. In some embodiments, the diameter of the second through hole 382 may be within a range of 40 mm-100 mm. In some embodiments, the diameter of the second through hole 382 may be within a range of 50 mm-90 mm. In some embodiments, the diameter of the second through hole 382 may be within a range of 60 mm-80 mm. In some embodiments, the diameter of the second through hole 382 may be within a range of 70 mm-75 mm.

The shape of the first hump 391 may be a cylinder, a cube, or a polygon. The first hump 391 and the second through hole 382 may be concentrically provided. The shape and/or dimension of the second through hole 382 are adapted to the shape and/or dimension of the first hump 391 such that the first hump 391 may be disposed within the second through hole 382 without substantial movement (e.g., a movable distance is less than a preset threshold). Specifically, the shape and/or dimension of the second through hole 382 adapted to the shape and/or dimension of the first hump 391 may be that the shape of the first hump 391 is the same as or substantially the same as the shape of the second through hole 382, and that the dimension of the second through hole 382 is slightly larger than the dimension of the first hump 391 and that the difference between the dimension of the second through hole 382 and the dimension of the first hump 391 is less than a second preset dimension threshold (e.g., 3 mm). The second preset dimension threshold may be a default value or may be adjusted depending on the situation. For example, if the shape of the first hump 391 is a cylinder, the shape of the second through hole 382 is also a cylinder, and the diameter of the second through hole 382 is slightly larger than the diameter of the first hump 391 (e.g., the diameter of the first hump 391 is 5 cm and the diameter of the second through hole 382 is 5.3 cm).

By setting the shape and/or dimension of the second through hole 382 to be adapted with the shape and/or dimension of the first hump 391, the second pressure member 390 may be placed within the first pressure member 380 and the first hump 391 may cooperate with the second through hole 382, and the nested connection of the first pressure member 380 and the second pressure member 390 may be realized, thereby making the overall structural connection of the bonding assembly 300 more stable.

In some embodiments, when the cross-section of the first air venting hole 383 is circular, the diameter of the cross-section of the first air venting hole 383 may be within a range of 0.01 mm-10 mm. In some embodiments, when the cross-section of the first air venting hole 383 is circular, the diameter of the first air venting hole 383 may be within a range of 0.1 mm-9 mm. In some embodiments, when the cross-section of the first air venting hole 383 is circular, the diameter of the first air venting hole 383 may be within a range of 1 mm-8 mm. In some embodiments, when the cross-section of the first air venting hole 383 is circular, the diameter of the first air venting hole 383 may be within a range of 2 mm-7 mm. In some embodiments, when the cross-section of the first air venting hole 383 is circular, the diameter of the first air venting hole 383 may be within a range of 3 mm-6 mm. In some embodiments, when the cross-section of the first air venting hole 383 is circular, the diameter of the first air venting hole 383 may be within a range of 4 mm-5 mm. By reasonably setting the dimension of the first vent hole 383, the venting effect during the bonding and fixing process of the seed crystal 130 may be strengthened, to enhance the bonding and fixing effect and improve the quality of the prepared crystal.

In some embodiments, after the first pressure member 380 and the second pressure member 390 are nested and connected, a vertical distance between the first air venting hole 383 and the upper surface of the second pressure member 390 is within a range of 0.2 mm-5 mm. In some embodiments, after the first pressure member 380 and the second pressure member 390 are nested and connected, the vertical distance between the first air venting hole 382 and the upper surface of the second pressure member 390 may be within a range of 0.5 mm-4.5 mm. In some embodiments, after the first pressure member 380 and the second pressure member 390 are nested and connected, the vertical distance between the first air venting hole 383 and the upper surface of the second member 390 may be within a range of 1 mm-4 mm. In some embodiments, after the first pressure member 380 and the second pressure member 390 are nested and connected, the vertical distance between the first air vent hole 383 and the upper surface of the second pressure member 390 may be within a range of 2 mm-3 mm. By controlling the vertical distance between the first air venting hole 383 and the upper surface of the second pressure member 390, the venting effect during the bonding and fixing process of the seed crystal 130 may be strengthened, which enhances the bonding and fixing effect and improves the quality of the prepared crystal.

In some embodiments, the sidewall of the second pressure member 390 includes at least one second air venting hole 393. As shown in FIG. 13, the at least one second air venting hole 393 may run horizontally through a sidewall of a slot 392 on the second pressure member 390. The slot 392 is configured to hold the seed crystal 130. The at least one second air venting hole 393 may be uniformly and symmetrically disposed on the sidewall of the slot 392, and the at least one second air venting hole 393 may be disposed at the same height in the vertical direction.

The first air venting hole 383 corresponds at least partially with the second air venting hole 393. For example, after the first pressure member 380 and the second pressure member 390 are nested and connected, the first air venting hole 383 overlaps with some or all of the second air venting hole 393, or the first air venting hole 383 is set concentrically with the second air venting hole 393 after the first pressure member 380 and the second pressure member 390 are nested and connected. The dimensions of the first air venting hole 383 and the second air venting hole 393 may be the same or different.

In some embodiments of the present disclosure, the first air venting hole 383 at least partially corresponds to the second air venting hole 393, which may improve the venting effect during the bonding process of the seed crystal 130 and help to improve the quality of the prepared crystal.

In some embodiments, a cross-sectional diameter of the second air venting hole 393 may be within a range of 0.01 mm-10 mm, to improve the venting effect during bonding of the seed crystal 130. In some embodiments, when the cross-section of the second air venting hole 393 is circular, the diameter of the second air venting hole 393 may be within a range of 1 mm-8 mm. In some embodiments, when the cross-section of the second air venting hole 393 is circular, the diameter of the second air venting hole 393 may be within a range of 2 mm-7 mm. In some embodiments, when the cross-section of the second air venting hole 393 is circular, the diameter of the second air venting hole 393 may be within a range of 3 mm-6 mm. In some embodiments, when the cross-section of the second air venting hole 393 is circular, the diameter of the second air venting hole 393 may be within a range of 4 mm-5 mm.

In some embodiments, a vertical distance between the second air venting hole 393 and the upper surface of the second pressure member 390 is within a range of 0.2 mm-5 mm to improve the venting effect during bonding of the seed crystal 130. In some embodiments, the vertical distance between the second air venting hole 393 and the upper surface of the second pressure member 120 may be within a range of 0.5 mm-4.5 mm. In some embodiments, the vertical distance between the second air venting hole 393 and the upper surface of the second pressure member 390 may be within a range of 1 mm-4 mm. In some embodiments, the vertical distance between the second air venting hole 393 and the upper surface of the second pressure member 390 may be within a range of 2 mm-3 mm.

In some embodiments, the height of the second pressure member 390 may be less than the height of the first pressure member 380, so that after the second pressure member 390 is nested with the first pressure member 380, the second pressure member 390 may be disposed in the internal cavity 381 of the first pressure member 380 within the first pressure member 380.

In some embodiments, the seed crystal holder 100 and the first pressure member 380 may be threaded. The upper portion of the sidewall of the internal cavity 381 of the first pressure member 380 may be provided with a threaded structure, and the sidewall of the seed crystal holder 100 may be provided with a threaded structure. After the seed crystal holder 100 is threadedly connected to the first pressure member 380, the second pressure member 390 may be disposed within a cavity enclosed by the seed crystal holder 100 and the first pressure member 380.

In some embodiments, the bottom of the first pressure plate 322 includes a second hump 3221, an upper portion of the seed crystal holder 100 includes a second groove 3222, and the second hump 3221 cooperates with the second groove 3222 to realize a connection between the first pressure plate 380 and the seed crystal holder 100.

The shape of the second hump 3221 may be a cylinder, a cube, or a polygon. The sidewall of the second hump 3221 may be provided with a threaded structure, the inner sidewall of the second groove 3222 may be provided with a threaded structure, and the second hump 3221 may be threadedly connected to the second groove 3222. By providing the second groove 3222 threadedly connected with the second hump 3221, the second groove 3222 is configured to cooperate with the second hump 3221, thereby realizing the connection of the first pressure plate 322 and the seed crystal holder 100. In turn, squeezing and venting the seed crystal 130 and the adhesive in stages at different temperatures or different pressures is realized to well bond the seed crystal 130 to the seed crystal holder 100.

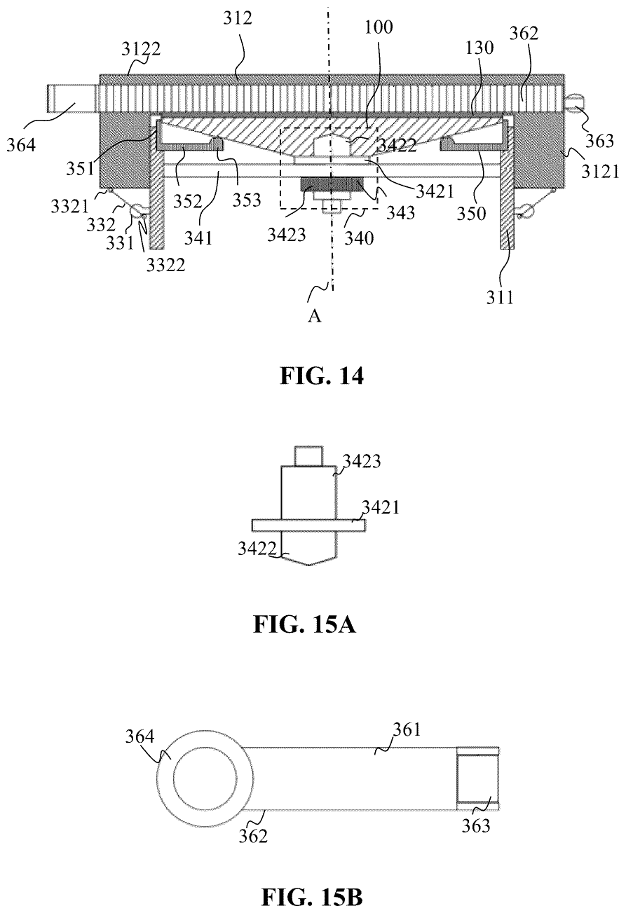

In some embodiments, the support member 310 may further include an annular base 311 and a cover body 312, and the seed crystal holder 100 may be provided on the annular base 311. The annular base 311 may be cylindrical, and a diameter of the annular base 311 may be greater or less than a maximum diameter of the seed crystal holder 100 (e.g., the diameter of the seed crystal bonding surface 111). When the diameter of the annular base 311 is larger than the maximum diameter of the seed crystal holder 100, the seed crystal bonding surface 111 may be smoothly placed on the annular base 311. When the diameter of the annular base 311 is smaller than the maximum diameter of the seed crystal holder 100, the outer surface of the seed crystal holder 100 may be placed on the annular base 311. The cover body 312 may also be cylindrical. As shown in FIG. 14, the cover body 312 includes an annular sidewall 3121 and a cover plate 3122, and the annular sidewall 3121 may be socketed outside the annular base 311. In some embodiments, an inner wall of the annular sidewall 3121 may be affixed to an outer wall of the annular base 311. The cover plate 3122 may be an internally hollow cylindrical shape disposed at an upper end portion of the annular base 311 as illustrated in FIG. 14, and an area of a cross-section of the cover plate 3122 along the axis A perpendicular to the seed crystal holder 100 is greater than an area of a cross-section of the bottom surface of the annular base 311 along the axis A perpendicular to the seed crystal holder 100. The cover body 312 may exert pressure toward the annular base 311 toward the seed crystal 130 affixed to the seed crystal holder 100. In some embodiments of the present disclosure, the seed crystal holder 100 is fixed by the annular base 311 while applying pressure to the seed crystal 130 through the cover body 312, so that the seed crystal 130 is pressed toward the seed crystal holder 100, thereby ensuring the seed crystal 130 to be quickly and easily bonded.

In some embodiments, the seed crystal bonding device 30 may further include a first connecting member 331 and a second connecting member 332. The first connecting member 331 may be provided on the annular base 311, and the second connecting member 332 may be provided on the cover body 312.

The first connecting member 331 may be detachably connected with the second connecting member 332. As shown in FIG. 14, the first connecting member 331 may be a structure such as a snap ring, a snap hook, a snap block, etc., provided on the sidewall of the annular base 311. The second connecting member 332 may include a positioning hump 3321 and a catch 3322, the positioning hump 3321 may be provided on a lower surface or a side surface of the annular sidewall 3121 of the cover body 312 as shown in FIG. 14 for fixing the second connecting member 332 to the cover body 312. The catch 3322 may be drivably connected to the positioning hump 3321, and the catch 3322 may be snapped into the first connecting member 331 for connecting the first connecting member 331 to the second connecting member 332. At this time, the cover plate 3122 of the cover body 312 applies pressure to the seed crystal 130 on the seed crystal holder 100 to bond the seed crystal 130. When the catch 3322 is disengaged from the first connecting member 331, the first connecting member 331 is disengaged from the second connecting member 332.

In some embodiments, the first connecting member 331 and the second connecting member 332 may be a connecting rope, with one end of the first connecting member 331 wrapped around an outer peripheral side of the annular base 311, one end of the second connecting member 332 wrapped around the lower surface or side surface of the annular sidewall 3121 of the cover body 312, and the other end of the first connecting member 331 connected to the other end of the second connecting member 332.

The seed crystal bonding device 30 may include a plurality of first connecting members 331 and a plurality of second connecting members 332. The plurality of first connecting members 331 cooperate with the plurality of second connecting members 332 in a one-to-one correspondence. As shown in FIG. 14, the seed crystal bonding device 30 may include two first connecting members 331 and two second connecting members 332, and each of the two first connecting members 331 cooperates with one of the two second connecting members 332.

Some embodiments of the present disclosure facilitate quick connection of the cover body 312 to the annular base 311 by the first connecting member 331 and the second connecting member 332, which in turn exerts pressure on the seed crystal holder 100. In addition, setting the first connecting member 331 and the second connecting member 332 as a removable connection may avoid the misalignment of the seed crystal holder 100 with the seed crystal 130 caused by the fixed connection, thus improving the bonding effect.

In some embodiments, a locking structure 340 may also be provided on the annular base 311. The locking structure 340 may be configured to fix the seed crystal holder 100 to the annular base 311 to improve the stability of the seed crystal holder 100 during the long process of crystal growth and to improve the quality of the crystal generation. For example, the locking structure 340 may include a pin. The seed crystal holder 130 and the annular sidewall 3121 may be provided with pin holes in a position and size matching the pin, and the pin may be inserted into the pin holes, thereby fixing the seed crystal holder 100 to the annular base 311.

In some embodiments, a connection threaded hole is provided on a side of the seed crystal holder 10 away from the seed crystal bonding surface 111, and the locking structure 340 includes a locking disk 341, a locking member, and a locking nut 343. As shown in FIG. 15A, the locking member may include a tray 3421, a first threaded rod 3422, and a second threaded rod 3423. The first threaded rod 3422 and the second screw 3423 may be disposed on two sides of a thickness direction of the tray 3421. As shown in FIG. 14, the first threaded rod 3422 may cooperate with a connection threaded hole (not shown) to be inserted into the connection threaded hole and thus threadedly connected to the seed crystal holder 100. In some embodiments, a threaded hole (not shown) may be provided in the tray 3421 so that it may be threaded to the first threaded rod 3422 to support the side of the seed crystal holder 100 away from the seed crystal bonding surface 111. In other embodiments, the first threaded rod 3422 may be fixed to the tray 3421 by a fixed connection such as bonding, welding, etc. The second threaded rod 3423 may be located on a side of the tray 3421 away from the seed crystal bonding surface 111 and threaded to the tray 3421. The locking disk 341 may be located on the side of the tray 3421 away from the seed crystal bonding surface 111, and the locking disk 341 may be a disk that fits against the inner wall of the annular base 311. The locking disk 341 may be provided with a mounting hole, and the second threaded rod 3423 may pass through the mounting hole to fit with the locking nut 343. The locking nut 343 and the tray 3421 may be disposed on two sides of the locking disk 341 along an axial direction of the mounting hole (the same as the thickness direction of the tray 3421). The axial direction of the mounting hole may be the same as the direction of axis A of the seed crystal holder 100. In some embodiments of the present disclosure, by connecting the connection threaded hole of the seed crystal holder 100 and the locking disk 341 through the locking member and fixing the connection threaded hole and the locking disk 341 through the locking nut 343, the seed crystal holder 100 may be stably fixed to the annular base 311, and at the same time cooperation of the annular base 311 and the locking disk 341 is conducive to improving the concentricity of the seed crystal holder 100 and the seed crystal 130.

In some embodiments, the tray 341 may be made of an elastic material (e.g., rubber, plastic) that may absorb pressure or friction of the seed crystal holder 100 during rotation to achieve a cushioning effect and may prevent the hot-pressing process from damaging the seed crystal holder body 110.

In some embodiments, the annular base 311 may also be provided with a support structure 350 on the inner wall of the annular base 311. As shown in FIG. 14, the support structure 350 may include an annular connecting plate 351, an annular support plate 352, and an annular support hump 353.

The annular connecting plate 351 may be configured to connect the inner wall of the annular base 311. The outer wall of the annular connecting plate 351 may be affixed to the inner wall of the annular base 311, and the shape of the annular connecting plate 351 may be adapted to the shape of the inner wall of the annular base 311. For example, the inner wall of the annular base 311 is cylindrical, and correspondingly, the annular connecting plate 351 is circular. The inner wall of the annular base 311 may be provided with a snapping recess matching the annular connecting plate 351, and the annular connecting plate 351 is embedded in the snapping recess.

The shape of the annular support plate 352 may be adapted to the shape of the annular connecting plate 351. For example, when the annular connecting plate 351 is a circle, correspondingly, the annular support plate 352 may be a circle. An outer ring of the annular support plate 352 connects the annular connecting plate 351, and the inner ring is provided with an annular support hump 353.

The annular support hump 353 may be configured to support the seed crystal support 100 and may include a semicircular or other shape (e.g., an inverted conical shape) in cross-section. The annular support hump 353 may be made of an elastic material (e.g., rubber) that absorbs pressure or friction of the seed crystal holder 100 during rotating, thereby achieving a cushioning effect that helps to protect the seed crystal holder body 110 during the hot-pressing process.

In some embodiments of the present disclosure, by providing the support structure 350, the seed crystal support 100 is stably supported, which effectively reduces the offset of the seed crystal support 100 after being pressurized, and the annular support protrusion 353 facilitates cooperating with the seed crystal support 100 of different tapers to be supported.

An adhesive may be used when bonding the seed crystal 130 and the seed crystal holder 100, and adhesive with viscosity in the bonding process may produce air bubbles. In some embodiments, the seed crystal bonding surface 111 may be provided with a coating, which may be a thermoplastic (e.g., polytetrafluoroethylene) that maintains the smoothness of the seed crystal bonding surface 111 so that air bubbles generated in the extrusion may be well expelled.

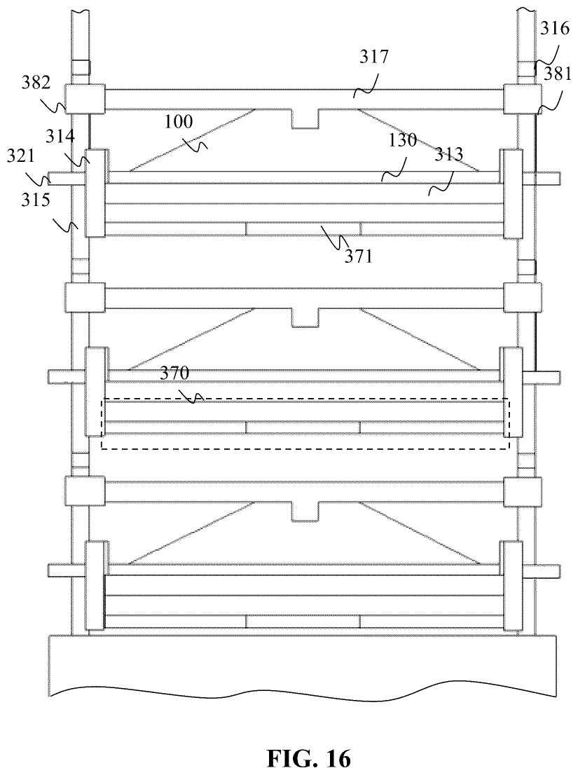

In some embodiments, the seed crystal bonding device may further include an air bubble removing apparatus. In some embodiments, the air bubble removing apparatus may be provided on the cover body 312, and the air bubble removing apparatus may be configured to remove air bubbles between the seed crystal 130 and the seed crystal holder 100. The air bubble removing apparatus may be provided between the cover body 312 and the seed crystal holder 100. In some other embodiments, the air bubble removing apparatus may include a device that drives the rotation of the seed crystal holder (e.g., a rotary driving member 370 as shown in FIG. 16 below, and more descriptions regarding the rotary driving member 370 may be found in FIG. 16 and its related description). When the air bubble removing apparatus includes the rotary driving member 370 shown in FIG. 16, the seed crystal holder 100, which has been bonded to the seed crystal 130, may be removed from the annular base 311, and then placed onto an apparatus that drives the seed crystal holder 100 to rotate, and the rotation of the seed crystal holder 100 under pressure provided by the cover body 312 may cause air bubbles between the seed crystal holder 100 and the seed crystal 130 to be expelled.

Some embodiments of the present disclosure may remove air bubbles by the air bubble removing apparatus to improve the bonding effect between the seed crystal 130 and the seed crystal holder 100.

As shown in FIG. 14 and FIG. 15B, the air bubble removing apparatus may also include an insert groove 361, an insert plate 362, and a roller 363. The insert groove 361 is provided on the cover body 312 to accommodate the insert plate 362 and limit the direction of movement of the insert plate 362. The insert plate 362 is in the form of a strip and is sized to fit into the insert groove 361. The insert plate 362 may be provided within the insert groove 361. The roller 363 may be provided at one end of the insert plate 362. A diameter of the roller 363 may be smaller than a height of the insert groove 361 to allow the roller 363 to move within the insert groove 361. The roller 363 may be made of an elastic material (e.g., rubber) to avoid damage to the seed crystal 130 or the seed crystal holder 100 during moving.

Before the seed crystal 130 is bonded, the insert plate 362 may support the seed crystal holder 100, and after the seed crystal 130 is bonded, the insert plate 362 may move (e.g., side-to-side) within the insert groove 361 to drive the roller 363 to roll the seed crystal 130. In some embodiments of the present disclosure, rolling the seed crystal 130 by driving the roller 363 through the insert plate 362 may squeeze out air bubbles generated by the seed crystal 130 during the bonding process and improve the quality of the bonding between the seed crystal 130 and the seed crystal holder 100.

As shown in FIG. 14 and FIG. 15B, the other end of the insert plate 362 may also be provided with a pull ring 364. After the seed crystal 130 is bonded, pulling the pull ring 364 may drive the insert plate 362 to move, which in turn drives the roller 363 to roll the seed crystal 130, thereby realizing the extrusion of the air bubbles.

In some embodiments, the air bubble removing apparatus may also include a rolling rotating member (not shown in the figures). The rolling rotating member may apply a certain amount of pressure to the seed crystal 130 in a direction toward the seed crystal bonding surface 111. At the same time, the rolling rotating member may also rotate with some fixed axis (e.g., axis A), and by applying pressure to the seed crystal 130 while rotating, the gas between the seed crystal 130 and the seed crystal holder 100 may be discharged. In the following embodiment, a surface on the rolling rotating member in contact with the seed crystal 130 may be provided with a rolling ball, a rolling post, a rolling wheel, or the like, to minimize friction between the rolling rotating member and the seed crystal 130.

In some embodiments, the support member 310 may include a support disk 313, as shown in FIG. 16. The support disk 313 is configured to support the seed crystal 130 and the seed crystal holder 100. In some embodiments, the support disk 313 may be disk-shaped, square disk-shaped, or the like. An area of the cross-section of the support disk 313 along the axis A perpendicular to the seed crystal holder 100 is greater than an area of the cross-section of the seed crystal holder 100 or the seed crystal 130 along the axis A perpendicular to the seed crystal holder 100. The seed crystal 130 is provided between the support disk 313 and the seed crystal holder 110.

In some embodiments, the seed crystal bonding device 30 may further include a support frame 314 and a plurality of pressure applying driving members provided on the support frame 314. The support disk 313 is provided on the support frame 314. The pressure applying driving members may include a pump-type apparatus (e.g., an electric pump) for driving the pressure applying member 320 to apply pressure to the seed crystal holder 100. In some embodiments, the pressure applying driving members may also include a pneumatic pressure applying driving member or a hydraulic pressure applying driving member.

In some embodiments, the seed crystal bonding device 30 may include a plurality of bonding assemblies 300, with the plurality of pressure applying driving members being connected to pressure applying member 320 in each of the bonding assemblies 300, respectively, so as to cause the pressure applying member 320 to apply pressure to the seed crystal holder 100 toward the support disk 313. When the pressure applying driving members apply pressure to the seed crystal support 100, the support disk 313 may support and limit the seed crystal support 10, to prevent the seed crystal support 100 from shifting. At the same time, the plurality of bonding assemblies 300 may be bonded simultaneously, thereby improving the bonding efficiency. As shown in FIG. 16, the seed crystal bonding device 30 may include three bonding assemblies 300 spaced apart in a vertical direction, with the vertical direction being the same as the axial direction of the seed crystal holder 100, and each of the bonding assemblies 300 may be configured to bond the seed crystal 130 of one seed crystal holder 100. When the pressure applying driving members simultaneously drive the pressure applying members 320 of the three bonding assemblies 300 to apply pressure to the corresponding seed crystal holder 100, a plurality of sets of seed crystals 130 may be bonded simultaneously.

As shown in FIG. 16, the support frame 314 may include a plurality of support rods 315 extending along the vertical direction. The support rods 315 are arranged at intervals along a circumferential direction of the support disk 313. The plurality of pressure applying driving members may be provided on at least one support rod 315 of the plurality of the support rods 315, the plurality of pressure applying driving members are spaced apart along the vertical direction, and the plurality of bonding assemblies 300 are spaced apart in the vertical direction to help the plurality of pressure applying driving members to apply pressure to bond the plurality of bonding assemblies 300 at one time, and to reduce space occupation.

In some embodiments, the support rod 315 provided with the pressure applying driving members may also be provided with a pressure-transferring medium passage, and at least one pressure applying driving member may be connected to the pressure-transferring medium passage via a valve 316. The valve 316 may be provided on the support rod 315 with the pressure applying driving member. By opening the valve 316, the seed crystal bonding device 30 may transmit pneumatic or hydraulic pressure generated by the pressure applying driving member through the pressure-transferring medium passage to transmit the pneumatic or hydraulic pressure to the pressure applying assembly 320 to apply pressure to the seed crystal holder 100 to apply pressure.

In some embodiments, the support disk 313 is rotatably provided on the support frame 314, and a rotation axis of the support disk 313 may be parallel to the support rod 314. The seed crystal bonding device 30 may also include a rotary driving member 370 connected with the support disk 313 to drive the support disk 313 to rotate. For example, the rotary driving member may include a motor, and the motor may drive the support disk 313 to rotate. As another example, the rotary driving member 370 may include a pneumatic driving member provided at the bottom of the support disk 313, the pneumatic driving member may be a circular turntable, and the bottom of the pneumatic driving member is connected to a gas compressor. The gas compressor may transmit compressed air to the pneumatic driving member to drive the pneumatic driving member to rotate, which in turn drives the rotation of the support disk 313.

In some embodiments of the present disclosure, by rotationally providing the support disk 313 on the support frame 314, the rotation of the support disk 313 may drive out air bubbles at the bonding place of the seed crystal 130, and it may effectively prevent the seed crystal 130 from disengaging due to weak bonding.

In some embodiments, the rotary driving member 370 may include a magnetic clement, a power source 371, and a magnetic driving member. The magnetic element may be fixed to the support disk 313. The magnetic driving member may be configured to drive the magnetic clement to rotate. In some embodiments, the magnetic driving member may be a circular turntable. The magnetic driving member may be fixed to an output end of the power source 371, with the magnetic driving member magnetically coupled to the magnetic element. The power source 371 may convert other energy sources into kinetic energy for driving the magnetic driving member to rotate. In some embodiments of the present disclosure, by driving the magnetic driving member to rotate by the power source 371, which in turn drives the magnetic clement to drive the support disk 313 to rotate, it is possible to control the rotation of the support disk 313 conveniently, thereby reducing friction and vibration produced during the rotation of the support disk 313.

In some embodiments, the pressure applying member 320 may include a limiting pressure plate 317 provided on the support frame 314. As shown in FIG. 16, in some embodiments, the limiting pressure plate 317 is a disk with a raised bottom, and the raised portion is connected (e.g., threaded or snap-connected) to the seed crystal holder 110.

In some embodiments, the pressure applying driving member may include a first sub-driving member 381 and a second sub-driving member 381. The first sub-driving member 381 and the second sub-driving member 382 may be provided on different support rods 314 to adjust the distance between different positions of the limiting pressure plate 317 and the support disk 313. The first sub-driving member 381 and the second sub-driving member 382 may be of the same structure. For example, the first sub-driving member 381 and the second sub-driving member 382 may both be movable support bases. The first sub-driving member 381 and the second sub-driving member 382 may be spaced apart along a circumferential direction of the limiting pressure plate 317, and both the first sub-driving member 381 and the second sub-driving member 382 are connected to the limiting pressure plate 317.

In some embodiments of the present disclosure, the first sub-driving member 381 and the second sub-driving member 381 may apply pressure to the seed crystal holder 100 from different positions, thereby avoiding uneven force on the seed crystal holder 100 due to applying pressure from a single position.

In some embodiments, the seed crystal bonding device 30 may further include a pressure sensor 321. The pressure sensor 321 is configured to determine a pressure applied by each pressure applying member 320. As shown in FIG. 16, in some embodiments, the pressure sensor 321 may be socketed at a site where the support rod 315 is connected to the support frame 314 and may be configured to sense the driving pressure of the pressure applying driving member and/or the pressure at the valve 316. In some other embodiments, the pressure sensor 321 may also be provided directly on the upper surface of the support disk 313 to directly sense the pressure applied to the seed crystal holder 100. Through the pressure sensor 321, the pressure at the seed crystal support 100 may be sensed directly or indirectly, which helps to well control the bonding process of the seed crystal 130, thereby facilitating timely adjustments in the event of too great pressure or too little pressure, and effectively preventing the seed crystal 130 from being crushed due to too much pressure or the bonding quality of the seed crystal 130 from being reduced due to too little pressure.

In some embodiments, the seed crystal bonding device 30 may further include a controller. The controller is in signal communication with both the valve 316 and the pressure sensor 321. In some embodiments, the controller may adjust an opening of the valve 316 based on pressure data sensed by the pressure sensor 321. For example, the controller may acquire the pressure data acquired by the pressure sensor 321 in real time. When the pressure data is less than a preset reference pressure minimum value, the controller may increase an opening degree of the valve 316 to improve the bonding effect of the seed crystal 130. When the pressure data is greater than a preset reference pressure maximum value, the controller may reduce the opening degree of the valve 316 to prevent the seed crystal 130 from being crushed. In some embodiments of the present disclosure, by determining the pressure data sensed by the pressure sensor 321, and then automatically regulating the opening degree of the valve 316, the pressure of each of the bonding assemblies 300 may be regulated so that each of the bonding assemblies 300 is subjected to a balanced force, which may effectively prevent the seed crystal 130 from being crushed due to too great pressure, or the bonding effect of the seed crystal 130 from being affected due to too little pressure.

The present disclosure also provides a crucible 400. The crucible 400 may be configured to generate the gas-phase component necessary for crystal growth. The feedstock (e.g., the molten liquid 140) in the crucible 400 may be volatilized into a gas-phase component under the action of the temperature field and move to the seed crystal 130 bonded to the seed crystal holder 100 in the upper portion, thereby enabling crystal growth.

In some embodiments, as shown in FIG. 17, the crucible 400 may include a crucible body 450, a driving assembly 460, and a temperature field holding disk 410.

The crucible body 450 is configured to carry the molten liquid 140 for crystal growth. The crucible body 450 may be in the shape of a cylinder, and the crucible body 450 may be provided with the molten liquid 140. By heating the crucible body 450 to heat the molten liquid 140, the seed crystal 130 in the seed crystal holder 100 comes into contact with the molten liquid 140, thereby realizing crystal growth.

The temperature field holding disk 410 may be configured to maintain a thermal field.

The driving assembly 460 may drive the crucible body 450 to rotate about an axis E of the crucible body 450 relative to the temperature field holding disk 410. The driving assembly 460 may include a driving source and a connecting mechanism 420, the connecting mechanism 420 may be connected between the driving source and a bottom of the crucible body 450, and the driving source may be provided at the bottom of the connecting mechanism 420 to provide a driving force for the driving assembly 460. The driving source may include a combination of various driving apparatuses and transmission apparatuses, and the driving apparatuses may include motors, hydraulic cylinders, pneumatic cylinders, or the like.

The temperature field holding disk 410 may be provided on the connecting mechanism 420 and between the driving source and the bottom of the crucible body 450. In some embodiments, the temperature field holding disk 410 may be disk-shaped or otherwise shaped. In some embodiments, the temperature field holding disk 410 is made of at least one of mullite, corundum, or alumina, and the above material settings may make the temperature field holding disk 410 adapt to a high-temperature environment, which may help improve the stability of the temperature field holding disk 410.

The temperature field holding disk 410 allows the thermal field to remain stationary as the crucible 400 rotates to prevent it from deflecting and tilting to cause it to contact the coil and fire, preventing it from continuing to grow the crystal. In addition, when the crucible 400 is moving up and down along the axis E of the crucible body 450, the temperature field holding disk 410 may also remain relatively stationary with the crucible 400, to maintain a stable temperature of the crucible 400 and guarantee the crystal quality of the crystal generation.

Some embodiments of the present disclosure may drive the crucible body 450 to rotate around the axis E of the crucible body 450 by setting the driving assembly 460, which may make the crucible 400 rotate in opposite directions to the seed crystals 130 and make the crucible 400 rotate alternately to the seed crystal 130, etc., so as to flush the steps formed on the crystal in different directions and thus reduce the width and the dimension of the steps, to make the crystal more flat and reduce the fluxes.

The rotation of the crucible body 450 may make the crystal flat and reduce the entrapped flux, which greatly improves the mass transfer of the melt and then effectively improves the thickness of the crystal.

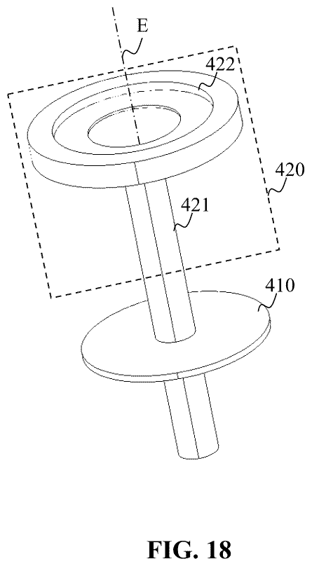

As shown in FIG. 18, the connecting mechanism 420 may include a rotating column 421 and a first bearing disk 422. The first bearing disk 422 is provided at one end of the rotating column 421, and the driving source is connected to the other end of the rotating column 421. As shown in FIG. 18, the first bearing disk 422 may be cylindrical for bearing the crucible body 450, and the rotating column 421 may be cylindrical for driving the first bearing disk 422 to rotate. The rotating column 421 may be connected to the driving source by a coupling, a bearing, etc. The material of the first bearing disk 422 may be graphite, and the material of the rotating column 421 may be a high-temperature-resistant material, such as mullite, corundum, aluminum oxide, or the like. Some embodiments of the present disclosure may further rotate the crucible body 450 in the first bearing disk 422 by driving the rotating column 421 by a driving source.

As shown in FIG. 1, a plurality of stepped grooves may be included in a concentric arrangement on the first bearing disk 4228. The plurality of stepped recesses are all concentric with the rotating column 421 and are dimensionally adapted to the dimensions of a plurality of different crucible bodies 450. In some embodiments of the present disclosure, by the concentrically arranged plurality of stepped grooves, a plurality of crucible bodies 450 with different dimensions may be located, and the crucible bodies 450 of different dimensions and shapes are replaced in conjunction with the actual situation, thereby preventing the crucible body 450 from being concentrically offset from the first bearing disk 422. In some embodiments, the plurality of stepped grooves on the first bearing disk 422 may also include a limiting structure (e.g., a rubber ring) that prevents the crucible body 450 from sliding during rotation.

In some embodiments, the connecting mechanism 420 further includes a second bearing disk 423. The second bearing disk 423 may be configured to bear the temperature field holding disk 410. The second bearing disk 423 may be made of at least one of a high-temperature-resistant material, such as mullite, corundum, or aluminum oxide.

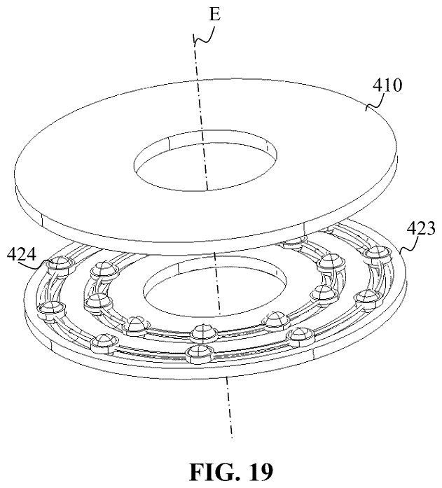

As shown in FIG. 19, in some embodiments, the shape of the second bearing disk 423 may be annular, and an inner ring of the second bearing disk 423 is fixed to an outer wall of the rotating column 421. The second bearing disk 423 may be located between the first bearing disk 422 and the driving source. In some embodiments, the second bearing disk 423 may be located at the bottom of the temperature field holding disk 410 and connected to the temperature field holding disk 410 by a ball structure 424. The second bearing disk 423 may include a plurality of ball structures 424, and the plurality of ball structures 424 may be fixed on the second bearing disk 423 by one or more positioning apparatuses. The plurality of ball structures 424 are uniformly distributed axially around the second bearing disk 423. As shown in FIG. 19, the ball structures 424 may be arranged as two sets of circular rows of different radii centered on the center of the second bearing disk 423. It is worth stating that the material of the thermal field is easy to powder, has low hardness and stability, and cannot ensure absolute balance when rotating, so the temperature field holding disk 410 may shift and tilt when rotating to cause it to contact the coil and fire, thereby failing to continue to grow the crystal. At the same time, the stability within the crucible body 450 may also be destabilized, leading to an increase in uncontrollable factors. Some embodiments in the present disclosure connect the second bearing disk 423 to the temperature field holding disk 410 by the ball structure 424, which may keep the stationary of the temperature field holding disk 410 while the rotating column 421 is rotating, thereby preventing an increase in the uncontrollable factors of the rotation of the temperature field holding disk 410.

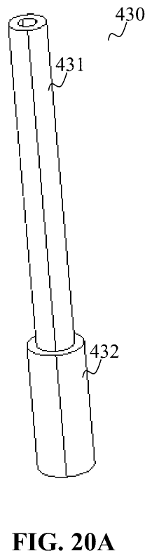

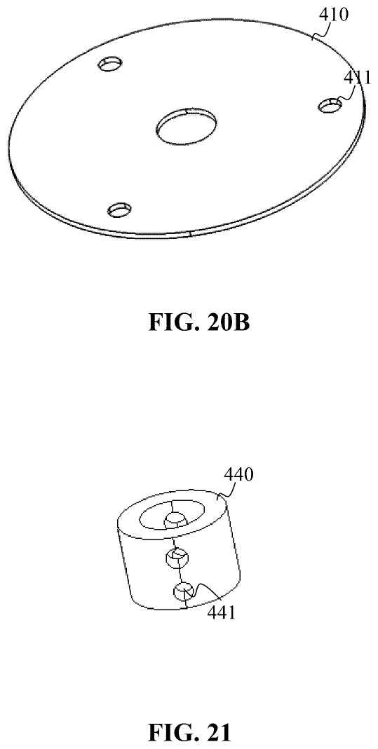

In some embodiments, the crucible 400 may also include a plurality of telescopic support rods 430. The telescopic support rods 430 may be configured to support the temperature field holding disk 410, with one end of each of the telescopic support rods 430 connected to the bottom of the temperature field holding disk 410. As shown in FIG. 20A, the telescopic support rods 430 may include a sliding rod 431 and a fixing rod 432, the sliding rod 431 may be moved upward and downward along an axial direction of the telescopic support rod 430, and the sliding rod 431 may be fixed with the fixing rod 431 by tightening threads or other locking mechanism. One end of the sliding rod 431 away from the fixing rod 432 may be connected to a fourth through hole 411 of the temperature field holding disk 410. As shown in FIG. 20B, there may be three fourth through holes 411 in the temperature field holding disk 410 that are uniformly spaced axially around the temperature field holding disk 410, and a dimension of each of the fourth through holes 411 is adapted to the sliding rod 431. The sliding rod may pass through the fourth through holes 411 via a threaded connection, etc., and be fixed in the temperature field holding disk 410. In some embodiments of the present disclosure, by the plurality of telescopic support rods 430, the temperature field holding disk 410 is prevented from tilting during the rotation of the crucible 400 and thus ensure the normal growth of the crystal.

In some embodiments, the crucible 400 may further include a connecting ring 440 and a locking mechanism. The locking hole 441 is in conjunction with the locking mechanism to fix the connecting ring 440 to the output shaft of the driving source and the rotating column 421. As shown in FIG. 21, the connecting ring 440 may be an internally hollow cylinder with a plurality of locking holes 441 symmetrically located along the axial direction of the connecting ring 440 on its sidewall, and the connecting ring 440 may be socketed on an output shaft of the driving source and the other end of the rotating column 421 (e.g., the end that is close to the driving source). The locking mechanism may be a screw, the dimension of the locking hole 441 is adapted to the locking mechanism, and the connecting ring 440 may be fixed to the output shaft of the driving source and the rotating column 421 by the cooperation between the locking mechanism and the locking hole 441. Some embodiments of the present disclosure may fix the output shaft of the driving source and the rotating column 421 to the connecting ring 440 by the connecting ring 440 and the locking mechanism, so that the driving source may stably drive the rotating column 421 to rotate to prevent the rotating column 421 from disengaging from the driving source while rotating.

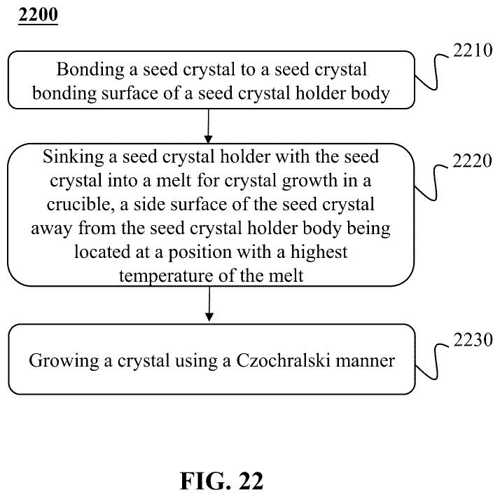

In some embodiments, the seed crystal holder 110 may be subjected to crystal growth by a crystal growth method as described in process 2200 shown in FIG. 22.

FIG. 22 is a flowchart illustrating an exemplary crystal growth method according to some embodiments of the present disclosure. In some embodiments, the crystal growth method may be accomplished by using a seed crystal holder (such as the seed crystal holder shown in FIG. 10). As shown in FIG. 22, process 2200 includes the following operations.

In 2210, a seed crystal is bonded to a seed crystal bonding surface of a seed crystal holder body.

The seed crystal may be bonded to the seed crystal bonding surface. In some embodiments, the seed crystal may be fixed by graphite paper. More descriptions regarding the seed crystal bonding surface and the graphite paper may be found in relevant previous sections, such as FIG. 1, and FIG. 10, etc.

In some embodiments, the operation of bonding the seed crystal to the seed crystal bonding surface of the seed crystal holder body includes causing a diameter of the seed crystal to be slightly larger than a diameter of the seed crystal holder body and the seed crystal to protrude slightly from a side surface of a protective bracket away from the connecting rod.

In some preferred embodiments, when bonding the seed crystal to the seed crystal bonding surface of the seed crystal holder body, the diameter of the seed crystal is larger than the diameter of the seed crystal holder body by 5 mm-10 mm, and the seed crystal protrudes from the side surface of the protective bracket away from the connecting rod by 0.1 mm-0.2 mm. In addition, the protection bracket may also be wrapped around the seed crystal to realize axial and radial temperature gradient control. The protection bracket also has a protective effect on the seed crystal. For example, after the seed crystal is immersed in the protective bracket, the seed crystal is not subjected to force when it is lifted and pulled, which prevents the seed crystal from falling off.

In some embodiments of the present disclosure, when bonding the seed crystal, making the diameter of the seed crystals slightly larger than the diameter of the seed crystal holder body and the seed crystal slightly protruding from the side surface of the protective bracket away from the connecting rod may ensure sufficient contact between the seed crystal and the molten liquid.

In some embodiments, when the seed crystal holder has components such as the protective bracket 180, the second protective sleeve 182, or the like as illustrated in FIG. 10, the operation of bonding the seed crystal to the seed crystal bonding surface of the seed crystal holder body may further include affixing the seed crystal to the end of the second protective sleeve 182 away from the connecting rod 120 and bonding the seed crystal to the seed crystal bonding surface 111 of the seed crystal holder body 110. This ensures that the second protective sleeve 182 is effective in preventing volatiles of the molten liquid from entering between the seed crystal and the protective bracket 180, as well as between the seed crystal holder body 110 and the protective bracket, during the crystal growth process.

In 2220, the seed crystal holder with the seed crystal is sunk into a melt for crystal growth in a crucible, and a side surface of the seed crystals away from the seed crystal holder body is located at a position with a highest temperature of the melt.

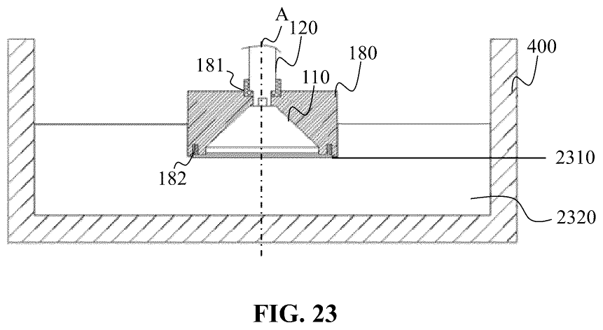

FIG. 23 is a schematic diagram illustrating a generated crystal according to some embodiments of the present disclosure. As shown in FIG. 23, the seed crystal holder may be immersed in a melt 2320 for crystal growth in the crucible 400. The melt 2320 is a molten state of the feedstock used to generate the crystal.

In some embodiments, the side surface of the seed crystal away from the seed crystal holder is substantially located at the position with the highest temperature of the melt. It is to be understood that a distance between the side surface of the seed crystal away from the seed crystal holder and a high temperature line where the temperature of the melt is highest is very small, such as less than 1% of the overall depth of the melt, etc. As in FIG. 23, the side surface of the seed crystal away from the seed crystal buttress is located at a high temperature line 2310 of the melt. The high temperature line 2310 may indicate the position with the highest temperature of the melt.

In some embodiments, a portion of the seed crystal holder is located in the melt and another portion of the seed crystal holder is located outside of the melt. Referring to FIG. 23, a portion of the seed crystal holder is located in the melt and another portion of the seed crystal holder is located outside of the melt. It is to be understood that a portion of the seed crystal holder being exposed outside the melt ensures control of the temperature gradient of the seed crystal holder in both the axial and radial directions and ensures a good growth of the crystal. In some embodiments, the seed crystal holder is kept out of contact with the melt as much as possible to avoid volatiles attaching to the seed crystal holder, which may make it difficult to achieve separation of crystal and holder after crystal growth. But the seed crystal holder trying not to be in contact with the melt is actually detrimental to crystal growth. Due to the setting of the protective bracket 180, in particular with the further setting of the first protective sleeve 181 and the second protective sleeve 182, the volatiles do not adhere to the seed crystal holder body. After solving this problem, the seed crystal holder may be partly disposed in the melt and partly disposed outside of the melt, and the seed crystal may be placed close to the high temperature line of the melt, which ensures that the crystal grows well.

In some embodiments, before immersing the seed crystal holder with the seed crystal into the melt for crystal growth, the operation further includes warming the melt to a preset temperature interval. In some preferred embodiments, the preset temperature interval at which the melt is warmed up may be within a range of 1720° C.-1780° C. It will be appreciated that warming the melt to the temperature interval of within a range of 1720° C.-1780° C. ensures sufficient melting of the melt for subsequent crystal growth.

In 2230, the crystal is grown using a Czochralski manner.

In some embodiments, the crystal may be grown by the Czochralski manner.

In some embodiments, the seed crystal holder is capable of rotating about the axis of the connecting rod, and the crucible is capable of rotating about the axis of the crucible. The axis of the connecting rod is parallel to the axis of the crucible.

As shown in FIG. 23, the seed crystal holder is capable of rotating about the axis A of the connecting rod, and the crucible is capable of rotating about the axis of the crucible. The axis of the crucible is parallel to the axis of the connecting rod.

In some embodiments, growing the crystal using the Czochralski manner further includes controlling the seed crystal holder and the crucible to rotate in opposite directions. In some embodiments of the present disclosure, by rotating the seed crystal holder and crucible in opposite directions, well lifting and pulling may be performed, increasing the crystal growth efficiency.

In some embodiments, a rotational speed of the seed crystal holder is within a range of 0 rpm-20 rpm; a rotational speed of the crucible is within a range of 0 rpm-20 rpm.

In some embodiments, the product of the numerical value of the rotational speed of the seed crystal holder and the numerical value of the rotational speed of the crucible is a preset value.

In some preferred embodiments, the product of the numerical value of the rotational speed of the seed crystal holder and the numerical value of the rotational speed of the crucible is 20 or 150.

In some embodiments of the present disclosure, controlling the product of the numerical value of the rotational speed of the seed crystal holder and the numerical value of the rotational speed of the crucible to be 20 or 150 ensures stable, fast, and high-quality crystal growth.

In some embodiments, growing the crystal using the Czochralski manner includes keeping the seed crystal holder with the seed crystal to be immersed in the melt for 10-30 minutes, and lifting the seed crystal holder at a lifting speed within a range of 0.01 mm/h-0.2 mm/h for crystal growth.

In some preferred embodiments, the lifting speed may be 0.05 mm/h.

In some embodiments of the present disclosure, by the embodiments described above, it is possible to ensure that the crystal is grown in a melt-stabilized condition.

In some embodiments, after the crystal is grown for 10 h-30 h, the crystal is lifted away from the melt at a lifting speed within a range of 30 mm/h-40 mm/h, and the crystal has a spacing height within a range of 15 mm-25 mm from the melt surface.

It is worth stating that, after a period of crystal growth, the height of the liquid level of the melt gradually decreases due to the corrosion of the crucible wall, evaporation of the melt, and other conditions, which causes the relative speed of the seed crystal to leave the melt to be accelerated gradually, resulting in the slow or even non-growth of the crystal growth. Based on the growth time, the lifting height, and the spacing height described in the foregoing embodiments may well overcome the above problems, resulting in better crystal growth.

In some embodiments, the crystal growth method further includes cutting the seed crystal holder along a cutting plane parallel to the seed crystal bonding surface to separate the seed crystal holder from the crystal after crystal growth is complete. The cutting plane covers the seed crystal holder body, the protective bracket, and the second protective sleeve. Because of the setting of the protective bracket and the second protective sleeve, there are no volatiles adhering between the seed crystal and the seed crystal holder body, and the seed crystal holder may be conveniently separated from the crystal by cutting.

In some embodiments of the present disclosure, the crystal growth method described in the above embodiments may easily separate the seed crystal due to the hindrance of adhesion caused by volatile substances, the lack of attachment of other substances between the seed crystal and the seed crystal holder body, and the diameter of the seed crystal being larger than the seed crystal holder body. Furthermore, the protective bracket may also ensure stable and efficient growth of the seed crystal while adjusting axial and radial temperature gradients. Thus, the crystal growth method described in the embodiments of the present disclosure may obtain the crystal efficiently and rapidly, and the crystal obtained is easy to separate.

It should be noted that the foregoing description of the process 2200 is intended to be exemplary and illustrative only and does not limit the scope of application of the present disclosure. For a person skilled in the art, various corrections and changes may be made to the process 2200 under the guidance of the present disclosure. However, these corrections and changes remain within the scope of the present disclosure.

Having thus described the basic concepts, it may be rather apparent to those skilled in the art after reading this detailed disclosure that the foregoing detailed disclosure is intended to be presented by way of example only and is not limiting. Although not explicitly stated here, those skilled in the art may make various modifications, improvements, and amendments to the present disclosure. These alterations, improvements, and amendments are intended to be suggested by this disclosure and are within the spirit and scope of the exemplary embodiments of the present disclosure.

Moreover, certain terminology has been used to describe embodiments of the present disclosure. For example, the terms “one embodiment,” “an embodiment,” and/or “some embodiments” mean that a particular feature, structure, or feature described in connection with the embodiment is included in at least one embodiment of the present disclosure. Therefore, it is emphasized and should be appreciated that two or more references to “an embodiment”, “one embodiment”, or “an alternative embodiment” in various portions of the present disclosure are not necessarily all referring to the same embodiment. In addition, some features, structures, or characteristics of one or more embodiments in the present disclosure may be properly combined.

Furthermore, the recited order of processing elements or sequences, or the use of numbers, letters, or other designations, therefore, is not intended to limit the claimed processes and methods to any order except as may be specified in the claims. Although the above disclosure discusses some embodiments of the invention currently considered useful by various examples, it should be understood that such details are for illustrative purposes only, and the additional claims are not limited to the disclosed embodiments. Instead, the claims are intended to cover all combinations of corrections and equivalents consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. However, this disclosure does not mean that object of the present disclosure requires more features than the features mentioned in the claims. Rather, claimed subject matter may lie in less than all features of a single foregoing disclosed embodiment.

In some embodiments, the numbers expressing quantities or properties used to describe and claim certain embodiments of the present disclosure are to be understood as being modified in some instances by the term “about”, “approximate”, or “substantially”. For example, “about”, “approximate”, or “substantially” may indicate ±20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the present disclosure are approximations, the numerical values set forth in the specific examples are reported as precisely as practicable.

Each of the patents, patent applications, publications of patent applications, and other material, such as articles, books, specifications, publications, documents, things, and/or the like, referenced herein is hereby incorporated herein by this reference in its entirety for all purposes. History application documents that are inconsistent or conflictive with the contents of the present disclosure are excluded, as well as documents (currently or subsequently appended to the present specification) limiting the broadest scope of the claims of the present disclosure. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the present disclosure disclosed herein are illustrative of the principles of the embodiments of the present disclosure. Other modifications that may be employed may be within the scope of the present disclosure. Thus, by way of example, but not of limitation, alternative configurations of the embodiments of the present disclosure may be utilized in accordance with the teachings herein. Accordingly, embodiments of the present disclosure are not limited to that precisely as shown and described.

1-26. (canceled)

27. A seed crystal bonding device, comprising one or more bonding assemblies, wherein the one or more bonding assemblies include a support member and a pressure applying member, the support member supports a seed crystal holder, the pressure applying member applies a pressure, and the pressure biaxially presses the seed crystal holder and the seed crystal on the seed crystal holder.

28. The seed crystal bonding device of claim 27, wherein
the support member includes a first pressure member and a second pressure member, and the pressure applying member includes a first pressure plate;
a sidewall of the first pressure plate includes at least one first air venting hole;
the second pressure member is nested to the first pressure plate;
during a bonding and fixation process of a seed crystal, the seed crystal is placed on an upper surface of the second pressure member and the seed crystal holder is placed on the upper surface of the seed crystal, and the first pressure plate applies pressure on the seed crystal holder.

29. The seed crystal bonding device of claim 28, wherein a bottom of the first pressure member includes a second through hole, a bottom of the second pressure member includes a first hump, and the first hump cooperates with the second through hole to realize a nested connection of the first pressure member and the second pressure member.

30. The seed crystal bonding device of claim 28, wherein a cross-sectional diameter of a first air venting hole of the at least one first air venting hole is within a range of 0.01 mm-10 mm; and/or
the second pressure member is nested to the first pressure plate, a vertical distance between the at least one first air venting hole and the upper surface of the second pressure member is within a range of 0.2 mm-5 mm.

31. (canceled)

32. The seed crystal bonding device of claim 28, wherein a sidewall of the second pressure member includes at least one second air venting hole, the at least one first air venting hole corresponds to at least portion of the at least one second air venting hole.

33-34. (canceled)

35. The seed crystal bonding device of claim 28, wherein a height of the second pressure member is less than a height of the first pressure member.

36. (canceled)

37. The seed crystal bonding device of claim 28, wherein a bottom of the first pressure plate includes a second hump and an upper portion of the seed crystal holder includes a second groove, and the second hump cooperates with the second groove to realize a connection between the first pressure plate and the seed crystal holder.

38. The seed crystal bonding device of claim 27, wherein the support member includes an annular base and a cover body, the seed crystal holder is provided on the annular base, the cover body includes an annular sidewall and a cover plate, the annular sidewall is socketed outside the annular base, and the cover body applies pressure on the seed crystal on the seed crystal holder.

39. The seed crystal bonding device of claim 38, further comprising a first connecting member and a second connecting member, wherein
the first connecting member is provided on the annular base, and the second connecting member is provided on the cover body;
the first connecting member is detachably connected with the second connecting member; and
when the first connecting member is connected with the second connecting member, the cover plate of the cover body applies pressure on the seed crystal on the seed crystal holder.

40. The seed crystal bonding device of claim 38, wherein the annular base is provided with a locking structure, and the locking structure fixes the seed crystal holder to the annular base:
a connection threaded hole is provided on a side of the seed crystal holder away from a seed crystal bonding surface,
the locking structure includes a locking disk, a locking member, and a locking nut,
the locking member includes a tray, a first threaded rod, and a second threaded rod,
the tray supports the side of the seed crystal holder away from the seed crystal bonding surface,
the first threaded rod cooperates with the connection threaded hole;
the locking disk is provided with a mounting hole,
the second threaded rod passes through the mounting hole,
the locking nut cooperates with the second threaded rod; and
the locking nut and the tray are provided on two sides of the locking disk along an axial direction of the mounting hole.

41-42. (canceled)

43. The seed crystal bonding device of claim 38, wherein an inner wall of the annular base is provided with a support structure, the support structure includes an annular connecting plate, an annular support plate, and an annular support hump; an outer ring of the annular support plate connects the annular connecting plate, an inner ring of the annular support plate is provided with the annular support hump, the annular support hump supports the seed crystal support, and the annular connecting plate connects the inner wall of the annular base.

44. The seed crystal bonding device of claim 38, wherein the cover body is provided with an air bubble removing apparatus, and the air bubble removing apparatus is configured to remove air bubbles between the seed crystal and the seed crystal holder, the air bubble removing apparatus includes an insert groove, an insert plate, and a roller; the insert groove is provided on the cover body, the insert plate is provided in the insert groove, the roller is provided at one end of the insert plate; and the insert plate is configured to move within the insert groove to drive the roller to roll the seed crystal.

45-46. (canceled)

47. The seed crystal bonding device of claim 27, further comprising a plurality of the bonding assemblies, the support member includes a support disk, the support disk is configured to support the seed crystal and the seed crystal holder, the seed crystal is located between the seed crystal and the seed crystal holder; and
the seed crystal bonding device further comprises a support frame and a plurality of pressure applying driving members provided on the support frame, the support disk is provided on the support frame, the seed crystal bonding device comprises the plurality of bonding assemblies, the plurality of pressure applying driving members are connected with a plurality of pressure applying members; the plurality of pressure applying driving members cause the plurality of pressure applying members to apply pressure on the seed crystal holder toward the support disk.

48. The seed crystal bonding device of claim 47, wherein the support frame includes a plurality of support rods extending along a vertical direction, the plurality of the support rods are arranged at intervals along a circumferential direction of the support disk, the plurality of the pressure applying driving members are provided on at least one support rod of the plurality of the support rods, the plurality of the pressure applying driving members are spaced apart along the vertical direction, and a plurality of seed crystal bonding assemblies are spaced apart along the vertical direction.

49. (canceled)

50. The seed crystal bonding device of claim 49, wherein at least one support rod provided with the plurality of the pressure applying driving members is provided with a pressure-transferring medium passage, and at least one pressure applying driving member is connected with the pressure-transferring medium passage through a valve.

51. The seed crystal bonding device of claim 47, wherein the support disk is rotatably disposed on the support frame, a rotation axis of the support disk is parallel to a support rod, and the seed crystal bonding device further comprises a rotary driving member connected with the support disk to drive the support disk to rotate.

52. The seed crystal bonding device of claim 51, wherein
the rotary driving member includes a magnetic element, a power source, and a magnetic driving member,
the magnetic driving member is magnetically coupled to the magnetic element,
the magnetic element is fixed on the support disk,
the magnetic driving member is fixed on an output end of the power source, and
the power source drives the magnetic driving member to rotate to drive the magnetic element to drive the support disk to rotate.

53. The seed crystal bonding device of claim 48, wherein the plurality of pressure applying members include limiting pressure plates provided on the plurality of support rods, the plurality of the pressure applying driving members include a first sub-driving member and a second sub-driving member, the first sub-driving member and the second sub-driving member are provided on different support rods of the plurality of support rods; and
the first sub-driving member and the second sub-driving member are spaced apart along a circumferential direction of the limiting pressure plates, and the first sub-driving member and the second sub-driving member are both connected with the limiting pressure plates.

54. The seed crystal bonding device of claim 48, further comprising a pressure sensor configured to determine a pressure applied by each of the plurality of pressure applying members.

55. The seed crystal device of claim 54, further comprising a controller, the controller is in signal communication with both the valve and the pressure sensor, and the controller is configured to:
adjust an opening of the valve based on pressure data sensed by the pressure sensor.

56-72. (canceled)
